(19) United States
(12) Patent Application Publication
(10) Pub. No.: US 2011/0062476 A1
(43) Pub. Date: Mar. 17, 2011

(54) LIGHT-EXTRACTION MEMBER, ORGANIC EL ELEMENT, AND METHOD FOR PRODUCING THE ORGANIC EL ELEMENT

(76) Inventor: Manabu TOBISE, Ashigarakami-gun (JP)

(21) Appl. No.: 12/880,927

(22) Filed: Sep. 13, 2010

(30) Foreign Application Priority Data
Sep. 14, 2009 (JP) 2009-212350

(51) Int. Cl. H01L 51/52; G02B 5/22; H01L 51/56

(52) U.S. Cl. 257/98; 359/891; 438/29; 257/E51.022

(57) ABSTRACT

A light-extraction member for use in a light-emitting display device, the light-extraction member including a light-extracting substrate which is disposed on the light-extraction side of the light-emitting display device, a color filter layer formed over the light-extracting substrate, and a lens member formed over the color filter layer, wherein the color filter layer is bonded via an adhesive portion to a convex top portion of the lens member.

### BACKGROUND OF THE INVENTION

1. Field of the Invention

The present invention relates to a light-extraction member, an organic EL element and a method for producing the organic EL element.

2. Description of the Related Art

Organic electroluminescence devices (organic EL devices) are self-emitting-type display devices, and are used in displays and lightings. Organic EL displays have several advantages over conventional CRTs or LCDs in terms of display performances, such as high visibility and less viewing-angle-dependency. Furthermore, organic EL lightings have advantages in that they can be made to be lightweight and thin-layered. In addition, organic EL lightings may open up a possibility of lightings with novel shapes through use of flexible substrates.

Although such organic EL devices possess several excellent characteristics as described above, the refractive indices of the constituent layers thereof, including a light-emitting layer, are generally higher than that of air. For example, the refractive indices of organic thin layers of organic EL devices (e.g., a light-emitting layer) are between 1.6 and 2.1. For this reason, emitted light tends to be totally reflected on the interfaces, and thus, the light-extraction efficiency is less than 20% and most of the emitted light is lost.

For example, an organic EL display part of generally known organic EL devices includes, on a substrate, an organic compound layer placed between a pair of electrode layers. The organic compound layer contains a light-emitting layer, and the organic EL devices emit, from a light-extraction surface, the light having been emitted from the light-emitting layer. In this case, these devices suffer low light-extraction efficiency, since the totally reflected components (i.e., light entering at an angle higher than the critical angle) cannot be extracted at the interfaces formed between the organic compound layer and the light-extraction surface or the electrode layers.

For this reason, some organic EL devices that have a light-extraction member (e.g., a lens) on a light path have been proposed to improve the light-extraction efficiency. In these organic EL devices, the lens controls the optical path of the light emitted from the light-emitting layer and makes the light to be emitted from the light-extraction surface.

For example, Japanese Patent (JP-B) No. 4239499 proposes an organic electroluminescence element including an anode, a cathode and a light-emitting part disposed therebetween, a lens portion, an air layer and a flattening surface, wherein the lens portion has substantially hemispherical microlenses at the opposite side to the light-emitting part across the cathode, the air layer is formed over substantially spherical surfaces of the microlenses in the lens portion, and the flattening surface is provided so as to partially come into contact with microlenses. In this element, light emitted from the light-emitting part is reflected on the microlenses, and the thus-reflected light enters the flattening surface, where the light is unfavorably guided in the flattening surface. This guided light enters optical paths of surrounding pixels to problematically cause bleeding thereof.

Japanese Patent Application Laid-Open (JP-A) No. 2003-031353 proposes a light-emitting element including a substrate, a first electrode disposed on the substrate, a light-emitting layer disposed on the first electrode, a transparent or semi-transparent second electrode disposed on the light-emitting layer and a lens disposed and arranged on the second electrode, wherein the lens is for collecting light emitted from the light-emitting layer and emitting the light to the outside of the system and wherein the diameter of the lens is 3/2 times or more greater than the width of the light-emitting layer. In this element, since the lens is formed directly on the light-emitting element; e.g., on the electrodes or the light-emitting layer formed on the substrate, components labile to, for example, heat are damaged to adversely affect the light-emission characteristics, which is problematic.

### BRIEF SUMMARY OF THE INVENTION

The present invention solves the above existing problems pertinent in the art and achieves the following objects. Specifically, an object of the present invention is to provide a light-extraction member involving less bleeding between pixels, an organic EL element containing the light-extraction member, and a method for producing the organic EL element. Another object of the present invention is to provide a method for producing an organic EL element involving less bleeding between pixels. The production method can produce the organic EL element so that the light-extraction efficiency thereof is not decreased. In addition, the production method can reduce damage of the organic EL element.

The present inventors conducted extensive studies and have found that the above problems can be solved by providing a color filter layer as a light-extraction member together with a lens member. The present invention has been accomplished on the basis of the finding.

<1> A light-extraction member for use in a light-emitting display device, the light-extraction member including:

a light-extracting substrate which is disposed on the light-extraction side of the light-emitting display device,

a color filter layer formed over the light-extracting substrate, and

a lens member formed over the color filter layer,

wherein the color filter layer is bonded via an adhesive portion to a convex top portion of the lens member.

<2> The light-extraction member according to <1>, wherein a flat portion is present on the side of the lens member opposite to the light-extraction side thereof.

<3> The light-extraction member according to one of <1> and <2>, wherein a space is present between the lens member and the color filter layer in a light-extracting direction.

<4> The light-extraction member according to any one of <1> to <3>, wherein the lens member has a refractive index of 1.4 to 2.1.

<5> The light-extraction member according to any one of <1> to <4>, wherein the lens member is a hemispherical lens.

<6> The light-extraction member according to any one of <1> to <5>, wherein the light-extracting substrate is made of a material having a water permeability of 0.1 g/m²/day or lower.

<7> The light-extraction member according to any one of <1> to <5>, wherein the light-extracting substrate is a barrier film composed of a plurality of layers.

<8> The light-extraction member according to any one of <1> to <7>, wherein the adhesive portion is the color filter layer.

<9> The light-extraction member according to any one of <1> to <7>, wherein the adhesive portion is a layer formed through coating of the same material as the lens member.

<10> An organic EL element including:

a light-extraction member for use in a light-emitting display device,

wherein the light-extraction member includes a light-extracting substrate which is disposed on the light-extraction side of the light-emitting display device, a color filter layer formed over the light-extracting substrate, and a lens member formed over the color filter layer, and

wherein the color filter layer is bonded via an adhesive portion to a convex top portion of the lens member.

<11> The organic EL element according to <10>, wherein the color filter layer includes a red filter portion, a green filter portion and a blue filter portion, which are located so that the red filter portion corresponds to an organic compound layer emitting red light, the green filter portion corresponds to an organic compound layer emitting green light, and the blue filter portion corresponds to an organic compound layer emitting blue light.

<12> The organic EL element according to <10>, wherein a flat portion is present at the lens member on the side opposite to the light-extraction side.

<13> The organic EL element according to <10>, wherein a space is present between the lens member and the color filter layer in a light-extracting direction.

<14> The organic EL element according to <10>, wherein the lens member has a refractive index of 1.4 to 2.1.

<15> The organic EL element according to <10>, wherein the light-extracting substrate is made of a material having a water permeability of 0.1 g/m²/day or lower.

<16> The organic EL element according to <10>, wherein the adhesive portion is the color filter layer.

<17> A method for producing an organic EL element, the method including:

forming a light-extraction member which includes a light-extracting substrate, a color filter layer and a lens member,

forming a light-emitting portion which includes at least a substrate, a pair of electrodes on the substrate, and a light-emitting layer between the electrodes, and

joining together the light-extraction member and the light-emitting portion.

<18> The method according to <17>, wherein the forming the light-extraction member includes forming the lens member on a temporary-bonding substrate, forming the color filter on the light-extracting substrate, bonding the color filter layer via an adhesive portion to a convex top portion of the lens member, and separating the temporary-bonding substrate from the lens member bonded to the color filter layer.

The light-extraction member and the organic EL element of the present invention can solve the above existing problems and achieve the above objects. Thus, the present invention can provide a light-extraction member involving less bleeding between pixels, an organic EL element containing the light-extraction member and a method for producing the organic EL element.

The method of the present invention for producing an organic EL element can produce an organic EL element involving less bleeding between pixels without decreasing the light-extraction efficiency of the organic EL element, while damage of the organic EL element is reduced.

### BRIEF DESCRIPTION OF THE DRAWINGS

FIG. 1 is a schematic cross-sectional view of one example of an organic EL element of the present invention.

FIG. 2 is a schematic cross-sectional view of another example of an organic EL element of the present invention.

FIG. 3A illustrates a step of forming a lens member, among steps of one exemplary method of the present invention for producing an organic EL element.

FIG. 3B illustrates a step of forming a light-extraction member, among steps of one exemplary method of the present invention for producing an organic EL element.

FIG. 3C illustrates a step of joining a light-extraction member with a light-emitting part, among steps of one exemplary method of the present invention for producing an organic EL element.

FIG. 4 illustrates an organic EL element of Example 5.

FIG. 5A is an explanatory view for Example 6 (part 1).

FIG. 5B is an explanatory view for Example 6 (part 2).

FIG. 6 is an explanatory view for a cylindrical lens.

### DETAILED DESCRIPTION OF THE INVENTION

### Light-Extraction Member and Organic EL Element

A light-extraction member of the present invention includes a substrate disposed on the light-extracting side (light-extracting substrate), a color filter layer and a lens member, and if necessary, includes other members. An organic EL element of the present invention includes the light-extraction member and, if necessary, other members. The light-extraction member of the present invention can be used in electroluminescence elements such as inorganic EL elements and organic EL elements, and known light-emitting display devices such as LEDs. The light-extraction member is preferably used in organic EL elements in terms of lamination structure and intended usage (color panel). Next, the light-extraction member will be described referring to an embodiment in which the light-extraction member is used in organic EL elements.

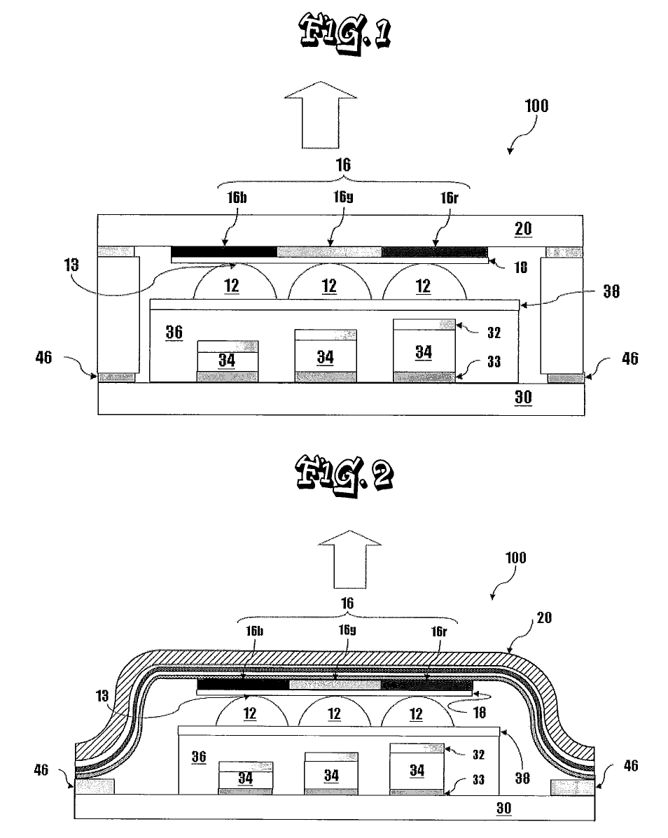

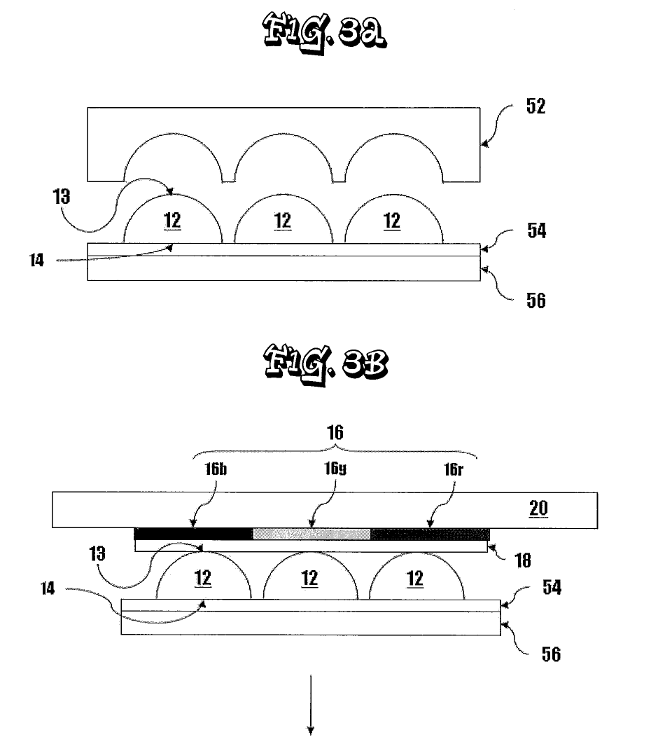

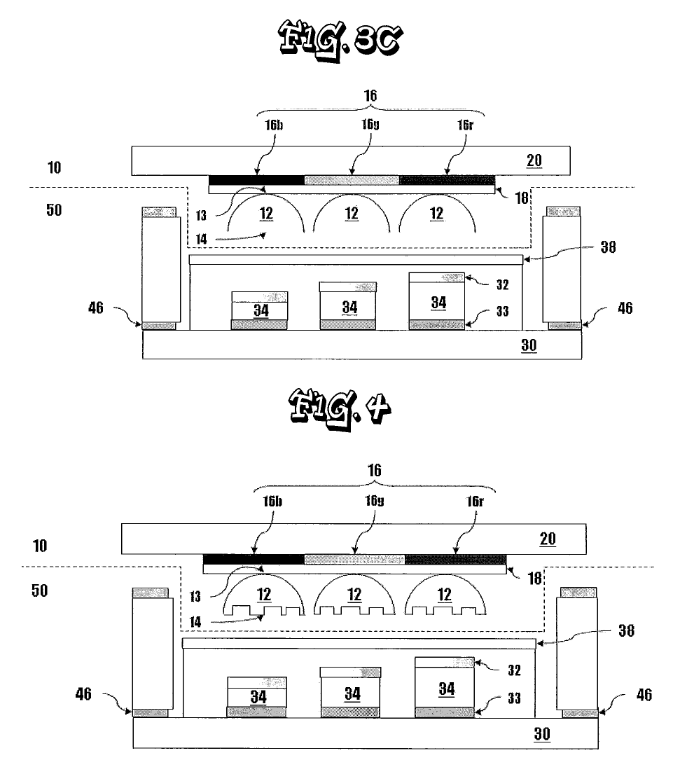

FIG. 1 is a schematic cross-sectional view of one example of an organic EL element of the present invention. FIG. 2 is a schematic cross-sectional view of another example of an organic EL element of the present invention. An organic EL element 100 has a substrate 30 (described below), an electrode 33 having reflectivity formed on the substrate 30, an electrode 32 having at least transmissivity, an organic compound layer 34 (including a light-emitting layer) disposed between the electrodes 32 and 33, a lens member 12 disposed on the light-extracting side of the organic EL element 100, a color filter layer 16 formed via an adhesive portion 18 on the lens member 12, and a light-extracting substrate 20 formed on the color filter layer 16. In the present invention, a light-extraction member 10 has, as illustrated in FIG. 3C, the light-extracting substrate 20 (which is formed at the light-extracting side of the organic EL element 100), the color filter layer 16 (which is formed on the light-extracting substrate 20) and the lens member 12 (which is formed on the color filter layer 16), wherein the color filter layer 16 is bonded via an adhesive portion 18 to a convex top portion 13 of the lens member 12. Notably, in FIGS. 1 and 2, the block arrows indicate a direction in which light is extracted from the organic EL element. Reference numeral 36 denotes a seal layer provided for sealing, from the outside, the electrodes 32 and 33 and the layers including the organic compound layer 34. Reference numeral 38 denotes a seal adhesive layer having the function of bonding the lens member 12. Reference numeral 46 denotes a sealing material for sealing the organic EL element from the surrounding environment.

### <Lens Member>

The lens member is not particularly limited, so long as it can extract, toward the light-emitted side of the organic EL element, light emitted from the light-emitting layer of the organic EL element, and may be appropriately selected depending on the intended purpose. The shape, structure, size, etc. of the lens member are not particularly limited and may be appropriately determined depending on the intended purpose. Examples of the lens member include convex lenses and concave lenses. Of these, convex lenses are preferred from the viewpoint of exhibiting high light-extraction efficiency. One or more types of the lens member may be used.

### —Convex Lens—

The convex lens is not particularly limited and may be appropriately selected depending on the intended purpose. Examples thereof include a hemispherical lens and a non-spherical lens. The shape of the convex lens may be, for example, a part of a sphere or a part of an oval sphere. The convex lens is not particularly limited and may be appropriately selected depending on the intended purpose. Examples thereof include a hemispherical lens formed by dividing a sphere in half. The size of the convex lens is not particularly limited and may be appropriately selected depending on the intended purpose. Preferably, the convex lens has such a size that covers one pixel from the viewpoint of exhibiting desired light-extraction efficiency. In particular, when the convex lens is disposed on the light-emitting surface of the light-emitting part so that the center of the convex lens and the center of the light-emitting surface are present on the same line in a perpendicular direction to the light-emitting surface, the smallest diameter of the convex lens is preferably 2.0 times to 4 times greater than the smaller length of the greatest lengths of the respective sides of the light-emitting surface of the light-emitting part. When the shape of the convex lens is a part of a sphere, the smallest diameter of the convex lens corresponds to the diameter of the sphere. When the shape of the convex lens is a part of an oval sphere, the smallest diameter of the convex lens corresponds to the minor axis of the oval sphere. When the shape of the light-emitting surface is a square, the greater length of the respective sides of the light-emitting surface of the light-emitting part corresponds to the length of one side of the square. When the shape of the light-emitting surface is a rectangle, the greater length of the respective sides corresponds to the length of the greater side of the rectangle. When the shape of the light-emitting surface is an equilateral triangle, the greater length of the respective sides corresponds to the length of one side of the triangle. When the shape of the light-emitting surface is an isosceles triangle in which each of the same two angles is less than 60°, the greater length of the respective sides corresponds to the length of the side other than the sides having the same length. When the light-emitting surface is not a square/rectangle but a polygon, the greater length of the respective sides corresponds to the length of the greatest side of the square/rectangle which is approximated so as to surround the polygon. Also, when the convex lens is a sphere, the center of the convex lens is the center of the sphere. When the convex lens is an oval sphere, the center of the convex lens is the intersection of the long side and the short side in the oval sphere. The center of the light-emitting surface is a centroid of the shape of the light-emitting surface.

The position at which the lens member is to be disposed is not particularly limited, so long as the lens member is disposed at the light-extracting side of the organic EL element (in a direction the organic compound layer 34 distances from the substrate 30 in FIG. 1), and may be appropriately determined depending on the intended purpose. For example, the lens member may be disposed so as to come into direct contact with an electrode through which light is emitted (the electrode 32 in FIG. 1). Alternatively, the lens member may be disposed on the seal adhesive layer 38 as illustrated in FIG. 1. Also, as illustrated in FIG. 1, the lens member may be positioned on the organic compound layer 34 (constituting one pixel) at the light-emitted side of the organic EL element. The distance between the lens member and the electrode through which light is emitted is not particularly limited and may be appropriately determined depending on the intended purpose. The distance therebetween is preferably 1 μm to 20 μm from the viewpoint of obtaining desired light-extraction efficiency.

The manner in which the lens member is disposed is not particularly limited and may be appropriately determined depending on the intended purpose. For example, when a pair of electrodes and an organic compound layer between the electrodes are regarded as one pixel, one or more of the lens member may be disposed so as to correspond to one pixel. Also, when two or more types of lens members are used, these lens members may be disposed in combination at an appropriate ratio.

The material for the lens member is not particularly limited and may be appropriately selected depending on the intended purpose. Various synthetic resins are exemplified. The resins are not particularly limited and may be appropriately selected. Examples thereof include UV-curable resins (e.g., epoxy resins and acrylic resins), theremosetting resins (e.g., phenol resins and melamine resins) and thermoplastic resins (e.g., polyethylenes and polycarbonates). The refractive index of the light-extracting structure is not particularly limited and may be appropriately determined depending on the intended purpose. The refractive index thereof is preferably 1.4 to 2.1 from the viewpoints of light-extraction efficiency and color tone. When the refractive index is less than 1.4, the light-extraction efficiency considerably decreases. Whereas when the refractive index exceeds 2.1, the wavelength dispersion becomes large, leading to decrease in color tone.

The method of forming the lens member is not particularly limited and may be appropriately selected depending on the intended purpose. Examples thereof include an inkjet method, an imprint method and a photolithography method. When the imprint method is employed, the lens member is formed as follows, for example. Specifically, a lens member coating is applied with a known coating method such as a spin coat method, a screen printing method or a dispenser method. After that, a lens member-forming mold having a predetermined shape and made of, for example, quartz, glass or resin is pressed against the coating, followed by curing through optional irradiation with UV rays. The cured coating may be heated at an appropriate temperature falling within a range of 100° C. to 150° C., in order to stabilize the material of the lens member. Before pressing of the lens member-forming mold having a predetermined shape, a known releasing agent may be applied on the mold in consideration of releasability thereof.

### —Lens Member-Forming Mold—

The lens member-forming mold used for the formation of the lens member is not particularly limited and may be appropriately selected depending on the intended purpose. Examples thereof include electron beam (EB) lithography, etching and laser writing. In one method of forming the lens member-forming mold, predetermined areas in the surface of a quartz substrate are exposed through photolithography including applying a photosensitive resist on the quartz substrate, and dry etching the areas to a predetermined depth. Alternatively, the areas may be irradiated with electron beams using an appropriate mask.

### <Color Filter Layer>

In the light-extraction member of the present invention, the color filter layer is not particularly limited, so long as it has chromaticness, and may be appropriately selected depending on the intended purpose. The color filter layer is, for example, a layer as illustrated in FIG. 1 or 2. When the color filter layer 16 is in the form of a layer, the color filter layer may have two or more different portions emitting lights of different colors on the same substrate. In to addition, as illustrated in FIGS. 1 and 2, the color filter layer may be a layer having portions of red, green and blue (i.e., three primary colors) like a red filter portion 16r, a green filter portion 16g and a blue filter portion 16b. Furthermore, as illustrated in FIGS. 1 and 2, the color filter layer may be disposed so that the red filter portion 16r corresponds to an organic compound layer emitting red light, the green filter portion 16g to an organic compound layer emitting green light, and the blue filter portion 16b to an organic compound layer emitting blue light.

The method of forming the color filter layer 16 is not particularly limited, so long as the above-described structure can be formed, and may be appropriately selected depending on the intended purpose. Examples thereof include a photolithographic method, an etching method and an inkjet method. The material for the color filter layer is not particularly limited and may be appropriately selected depending on the intended purpose. Examples thereof include various resins, dyes and pigments.

### <Light-Emitted Substrate>

In the light-extraction member of the present invention, the light-emitted substrate is not particularly limited, so long as it has light permeability and can support the light-extraction member, and may be appropriately selected depending on the intended purpose.

The shape, structure, size, etc. of the light-extracting substrate are not particularly limited and may be appropriately selected. In general, the light-extracting substrate is preferably a plate-like substrate. The substrate may have a single-layered structure as illustrated in FIG. 1 or a flexible, multi-layered structure as illustrated in FIG. 2. Also, the substrate may be a single member or formed from two or more members. The substrate may be colorless transparent or colored transparent, but is preferably colorless transparent from the viewpoint of avoiding scattering or damping light emitted from the below-described light-emitting layer of the organic EL element. The substrate having a multi-layered structure may be formed by appropriately combining layers such as a base layer (which imparts mechanical strength to the formed substrate), an inorganic layer (which has the function of sealing the organic EL element) and an organic layer (which covers pinholes and flattens concaves/convexes in the inorganic layer). The light-extracting substrate preferably has low water permeability from the viewpoint of sealing. For example, the light-extracting substrate may be made of a material having a water permeability of 0.1 g/m²/day or lower.

The material for the substrate is not particularly limited and may be appropriately selected depending on the intended purpose. Examples thereof include inorganic materials such as yttria-stabilized zirconia (YSZ) and glass; and organic materials such as polyesters (e.g., polyethylene terephthalate, polybutylene phthalate and polyethylene naphthalate), polystyrene, polycarbonate, polyether sulfone, polyarylate, polyimide, polycycloolefin, norbornene resins and poly(chlorotrifluoroethylene).

For example, when the substrate is made of glass, the glass is preferably alkali-free glass in order to reduce ions eluted from it. Also, when soda-lime glass is used for the material of the substrate, a barrier coat of silica, etc., is preferably provided on the substrate (e.g., barrier-film substrates). The organic materials are preferably used since they are excellent in heat resistance, dimensional stability, solvent resistance, electrical insulation and processability.

When a thermoplastic substrate is used, a hard coat layer, an under coat layer and other layers may be additionally provided as necessary.

### <Adhesive Portion>

In the light-extraction member of the present invention, an adhesive portion is not particularly limited, so long as it bonds the color filter layer to the convex top portion of the lens member, and may be appropriately determined depending on the intended purpose. The adhesive portion may be a layer as indicated by, for example, reference numeral 18 in FIGS. 1 and 2, or may have an adhesive ingredient only necessary portions for bonding the color filter layer 16 to the convex top portion 13 of the lens member 12. Alternatively, the above-described color filter layer 16 may have an adhesion function; i.e., the color filter layer 16 may be the adhesive portion 18. The material for the adhesive portion is not particularly limited and may be appropriately selected depending on the intended purpose. Examples of the material include photocurable resins and heat-curable resins. Examples of the photocurable resins include (meth)acrylic resins. Examples of the heat-curable resins include epoxy resins, phenol resins and polyimides.

### (Organic EL Element)

An organic EL element of the present invention includes at least the above-described light-extraction member and the below-described light-emitting part; and, if necessary, includes other members. The shape, structure, size, etc. of the organic EL element of the present invention are not particularly limited, so long as the organic EL element has the above-described structure, and may be appropriately determined depending on the intended purpose. One exemplary embodiment of the organic EL element will be described with reference to the drawings.

As illustrated in FIGS. 1 and 2, the organic EL element of the present invention includes the light-extraction member 10 having the lens member 12, the color filter layer 16 and the light-extracting substrate 20. Also, the organic EL element may include the below-described substrate 30, an electrode 33 having reflectivity and disposed on the substrate 30, an electrode 32 having at least transmissivity, and an organic compound layer 34 (including a light-emitting layer) disposed between the electrodes 32 and 33.

### <Light-Emitting Part>

In the organic EL element of the present invention, a light-emitting part is not particularly limited, so long as it contains the below-described electrodes and an organic compound layer (including a light-emitting layer) disposed between the electrodes, and may be appropriately selected depending on the intended purpose. If necessary, the light-emitting part may have the below-described layers/members having the function of injecting or transporting holes/electrons, or other functions. In addition, the light-emitting part may have other members, if necessary.

### <<Light-Emitting Layer>>

The light-emitting layer is not particularly limited, so long as it emits light when an electrical field is applied, and may be appropriately selected depending on the intended purpose. The light-emitting layer may be made of organic or inorganic light-emitting materials. In particular, organic light-emitting materials are preferably used from the viewpoints of exhibiting high light-emission efficiency and providing a larger device. Next, description will be given with respect to the organic compound layer containing the light-emitting layer made of the organic light-emitting material.

### <Organic Compound Layer>

The organic compound layer having a light-emitting layer containing an organic light-emitting material is not particularly limited and may be appropriately selected depending on the intended purpose. As a lamination pattern of the organic compound layer, preferably, a hole-transport layer, an organic light-emitting layer and an electron transport layer are laminated in this order from the anode side. Moreover, a hole-injection layer is provided between the hole-transport layer and the cathode, and/or an electron-transportable intermediate layer may be provided between the organic light-emitting layer and the electron transport layer. Also, a hole-transportable intermediate layer may be provided between the organic light-emitting layer and the hole-transport layer. Similarly, an electron-injection layer may be provided between the cathode and the electron-transport layer. Notably, each layer may be composed of a plurality of secondary layers. Notably, the anode, the cathode and the other layers than the organic light-emitting layer correspond to the above other layers/members.

The method for forming the layers constituting the organic compound layer is not particularly limited and may be appropriately selected depending on the intended purpose. The layers constituting the organic compound layer can be suitably formed by any of a dry film-forming method (e.g., a vapor deposition method and a sputtering method), a transfer method, a printing method, a coating method, an ink-jet method and a spray method. Among them, a vapor deposition method is preferably employed from the viewpoints of improving the service life of the formed element and attaining high throughput.

The organic light-emitting layer is a layer having the functions of receiving holes from the anode, the hole injection layer, or the hole-transport layer, and receiving electrons from the cathode, the electron-injection layer, or the electron transport layer, and providing a field for recombination of the holes with the electrons for light emission, when an electric field is applied.

The light-emitting layer may be composed only of a light-emitting material, or may be a layer formed form a mixture of a host material and a dopant. The dopant may be a light-emitting dopant. The light-emitting dopant may be a fluorescent or phosphorescent light-emitting material, and may contain two or more species. The host material is preferably a charge-transporting material. The host material may contain one or more species, and, for example, is a mixture of a hole-transporting host material and an electron-transporting host material. Further, a material which does not emit light nor transport any charge may be contained in the organic light-emitting layer.

The organic light-emitting layer may be a single layer or two or more layers. When it is two or more layers, the layers may emit lights of different colors.

The above light-emitting dopant is not particularly limited and may be appropriately selected depending on the intended purpose. The light-emitting dopant may be, for example, a phosphorescent light-emitting material (phosphorescent light-emitting dopant) and a fluorescent light-emitting material (fluorescent light-emitting dopant).

The organic light-emitting layer may contain two or more different light-emitting dopants for improving color purity and/or expanding the wavelength region of light emitted therefrom. From the viewpoint of drive durability, it is preferred that the light-emitting dopant is those satisfying the following relation(s) with respect to the above-described host compound: i.e., 1.2 eV>difference in ionization potential (ΔIp)>0.2 eV and/or 1.2 eV>difference in electron affinity (ΔEa)>0.2 eV.

The fluorescent light-emitting material is not particularly limited and may be appropriately selected depending on the intended purpose. Examples thereof include complexes containing a transition metal atom or a lanthanoid atom.

The transition metal atom is not particularly limited and may be selected depending on the intended purpose. Preferred are ruthenium, rhodium, palladium, tungsten, rhenium, osmium, iridium gold, silver, copper and platinum. More preferred are rhenium, iridium and platinum. Particularly preferred are iridium and platinum.

The lanthanoid atom is not particularly limited and may be appropriately selected depending on the intended purpose. Examples thereof include lanthanum, cerium, praseodymium, neodymium, samarium, europium, gadolinium, terbium, dysprosium, holmium, erbium, thulium, ytterbium and lutetium, with neodymium, europium and gadolinium being preferred.

Examples of ligands in the complex include those described in, for example, “Comprehensive Coordination Chemistry” authored by G. Wilkinson et al., published by Pergamon Press Company in 1987; “Photochemistry and Photophysics of Coordination Compounds” authored by H. Yersin, published by Springer-Verlag Company in 1987; and “YUHKI KINZOKU KAGAKU—KISO TO OUYOU—(Metalorganic Chemistry—Fundamental and Application—)” authored by Akio Yamamoto, published by Shokabo Publishing Co., Ltd. in 1982.

The ligands are not particularly limited and may be selected depending on the intended purpose. Preferred examples of the ligands include halogen ligands (preferably, chlorine ligand), aromatic carbon ring ligands (preferably 5 to 30 carbon atoms, more preferably 6 to 30 carbon atoms, still more preferably 6 to 20 carbon atoms, particularly preferably 6 to 12 carbon atoms, such as cyclopentadienyl anion, benzene anion and naphthyl anion); nitrogen-containing hetero cyclic ligands (preferably 5 to 30 atoms, more preferably 6 to 30 carbon atoms, still more preferably 6 to 20 carbon atoms, particularly preferably 6 to 12 carbon atoms, such as phenyl pyridine, benzoquinoline, quinolinol, bipyridyl and phenanthroline), diketone ligands (e.g., acetyl acetone), carboxylic acid ligands (preferably 2 to 30 carbon atoms, more preferably 2 to 20 carbon atoms, still more preferably 2 to 16 carbon atoms, such as acetic acid ligand), alcoholate ligands (preferably 1 to 30 carbon atoms, more preferably 1 to 20 carbon atoms, particularly preferably 6 to 20 carbon atoms, such as phenolate ligand), silyloxy ligands (preferably 3 to 40 carbon atoms, more preferably 3 to 30 carbon atoms, still more preferably 3 to 20 carbon atoms, such as trimethyl silyloxy ligand, dimethyl tert-butyl silyloxy ligand and triphenyl silyloxy ligand), carbon monoxide ligand, isonitrile ligand, cyano ligand, phosphorus ligand (preferably 3 to 40 carbon atoms, more preferably 3 to 30 carbon atoms, still more preferably 3 to 20 carbon atoms, particularly preferably, 6 to 20 carbon atoms, such as triphenyl phosphine ligand), thiolate ligands (preferably 1 to 30 carbon atoms, more preferably 1 to 20 carbon atoms, still more preferably 6 to 20 carbon atoms, such as phenyl thiolate ligand) and phosphine oxide ligands (preferably 3 to 30 carbon atoms, more preferably 8 to 30 carbon atoms, particularly preferably 18 to 30 carbon atoms, such as triphenyl phosphine oxide ligand), with nitrogen-containing hetero cyclic ligand being more preferred.

The above-described complexes may be a complex containing one transition metal atom in the compound, or a so-called polynuclear complex containing two or more transition metal atoms. In the latter case, the complexes may contain different metal atoms at the same time.

Among them, specific examples of the light-emitting dopants include phosphorescence luminescent compounds described in Patent Literatures such as U.S. Pat. No. 6,303,238B1, U.S. Pat. No. 6,097,147, International Publication Nos. WO00/57676, WO00/70655, WO01/08230, WO01/39234A2, WO01/41512A1, WO02/02714A2, WO02/15645A1, WO02/44189A1 and WO05/19373A2, JP-A Nos. 2001-247859, 2002-302671, 2002-117978, 2003-133074, 2002-235076, 2003-123982 and 2002-170684, EP1211257, JP-A Nos. 2002-226495, 2002-234894, 2001-247859, 2001-298470, 2002-173674, 2002-203678, 2002-203679, 2004-357791, 2006-256999, 2007-19462, 2007-84635 and 2007-96259. Among them, Ir complexes, Pt complexes, Cu complexes, Re complexes, W complexes, Rh complexes, Ru complexes, Pd complexes, Os complexes, Eu complexes, Tb complexes, Gd complexes, Dy complexes and Ce complexes are preferred, with Ir complexes, Pt complexes and Re complexes being more preferred. Among them, Ir complexes, Pt complexes, and Re complexes each containing at least one coordination mode of metal-carbon bonds, metal-nitrogen bonds, metal-oxygen bonds and metal-sulfur bonds are still more preferred. Furthermore, Ir complexes, Pt complexes, and Re complexes each containing a tri-dentate or higher poly-dentate ligand are particularly preferred from the viewpoints of, for example, light-emission efficiency, drive durability and color purity.

The fluorescence luminescent dopant is not particularly limited and may be appropriately selected depending on the intended purpose. Examples thereof include benzoxazole, benzoimidazole, benzothiazole, styrylbenzene, polyphenyl, diphenylbutadiene, tetraphenylbutadiene, naphthalimide, coumarin, pyran, perinone, oxadiazole, aldazine, pyralidine, cyclopentadiene, bis-styrylanthracene, quinacridone, pyrrolopyridine, thiadiazolopyridine, cyclopentadiene, styrylamine, aromatic dimethylidene compounds, condensed polyaromatic compounds (e.g., anthracene, phenanthroline, pyrene, perylene, rubrene and pentacene), various metal complexes (e.g., metal complexes of 8-quinolynol, pyromethene complexes and rare-earth complexes), polymer compounds (e.g., polythiophene, polyphenylene and polyphenylenevinylene), organic silanes and derivatives thereof.

The luminescent dopants may be appropriately selected depending on the intended purpose. Specific examples of the luminescent dopants include the following compounds, which should be construed as limiting the present invention thereto.

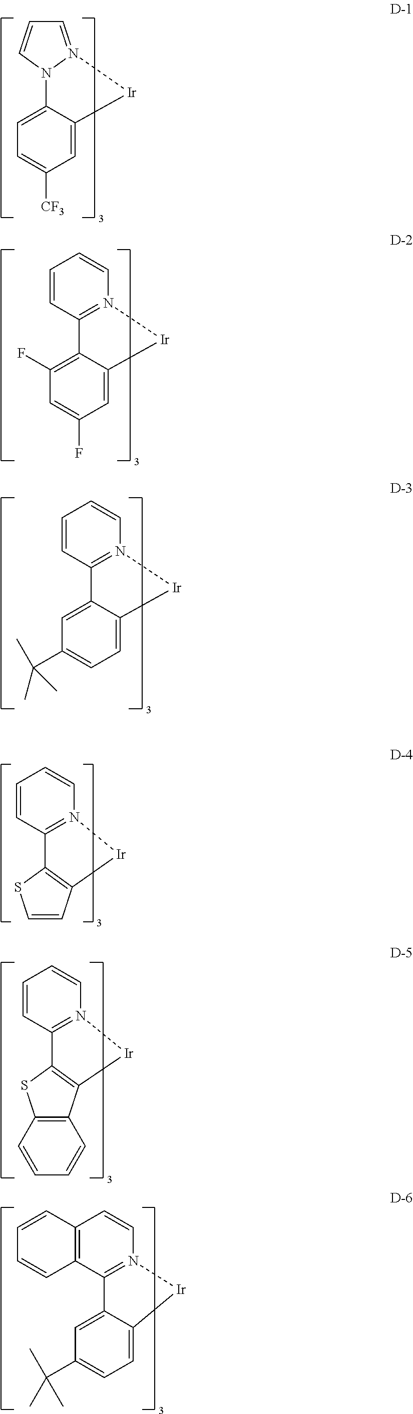

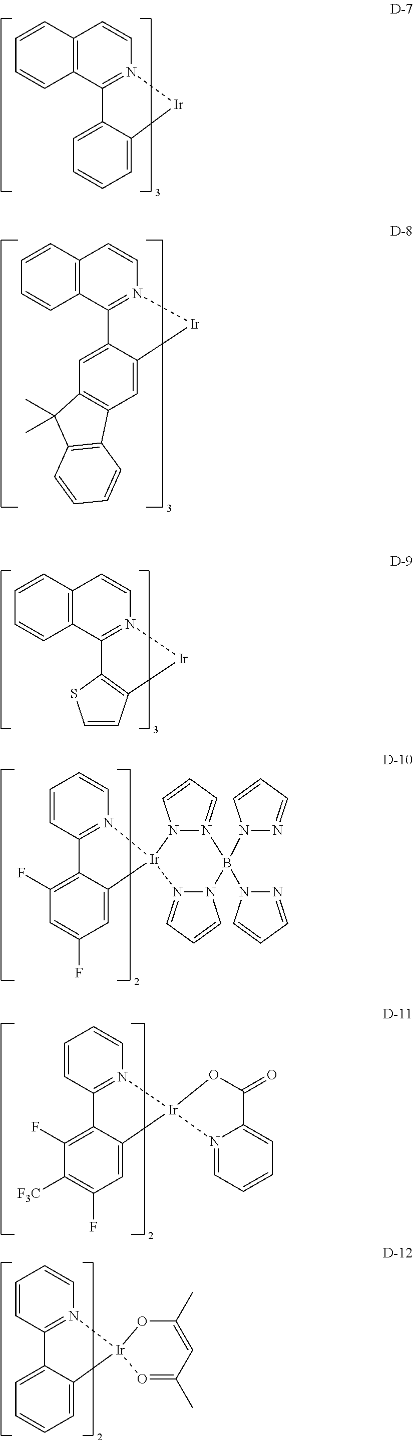

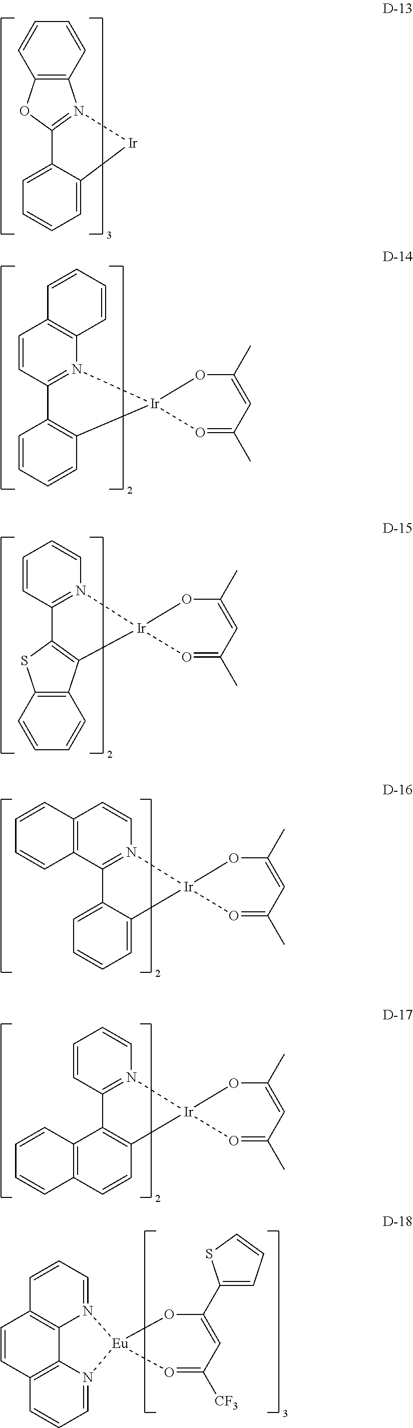

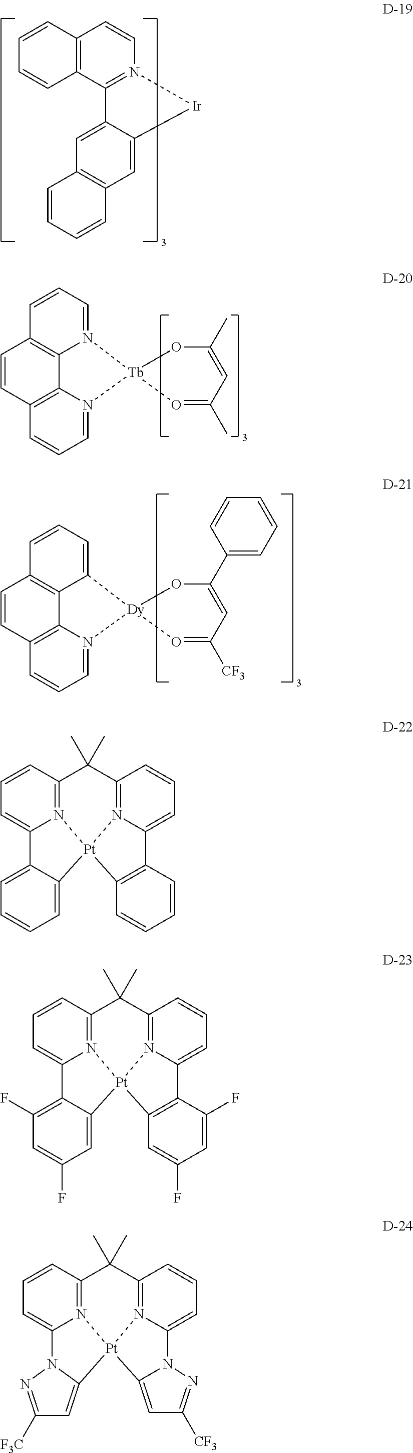

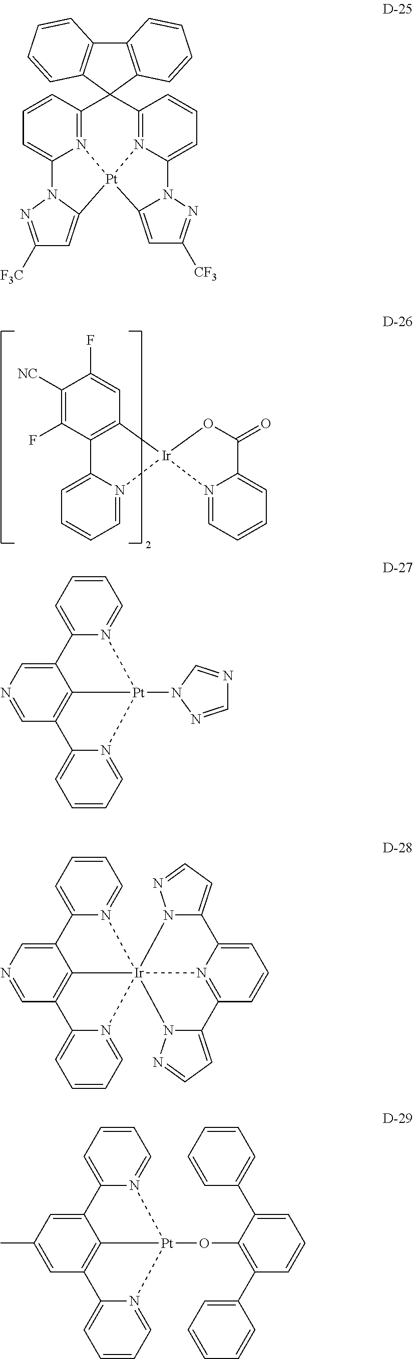

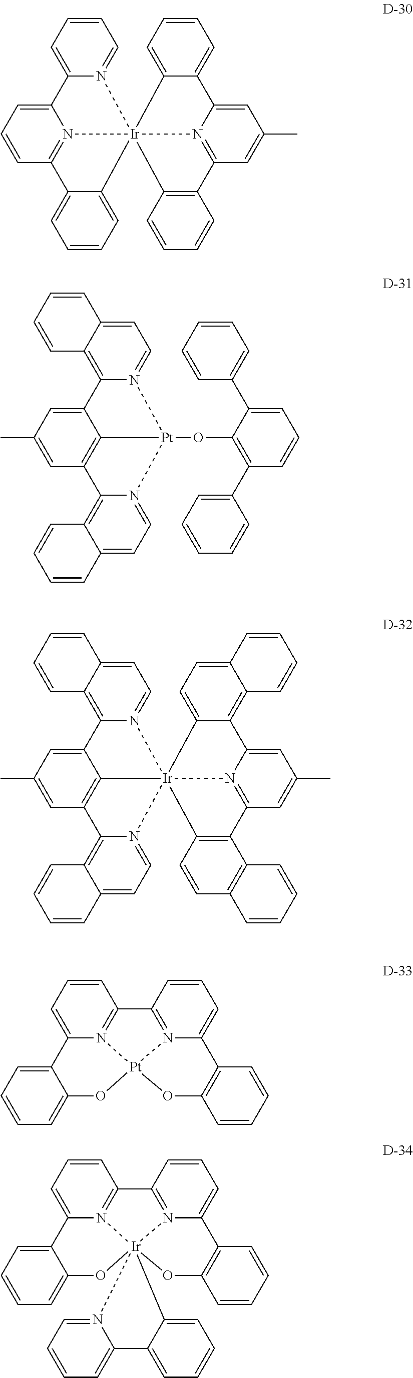

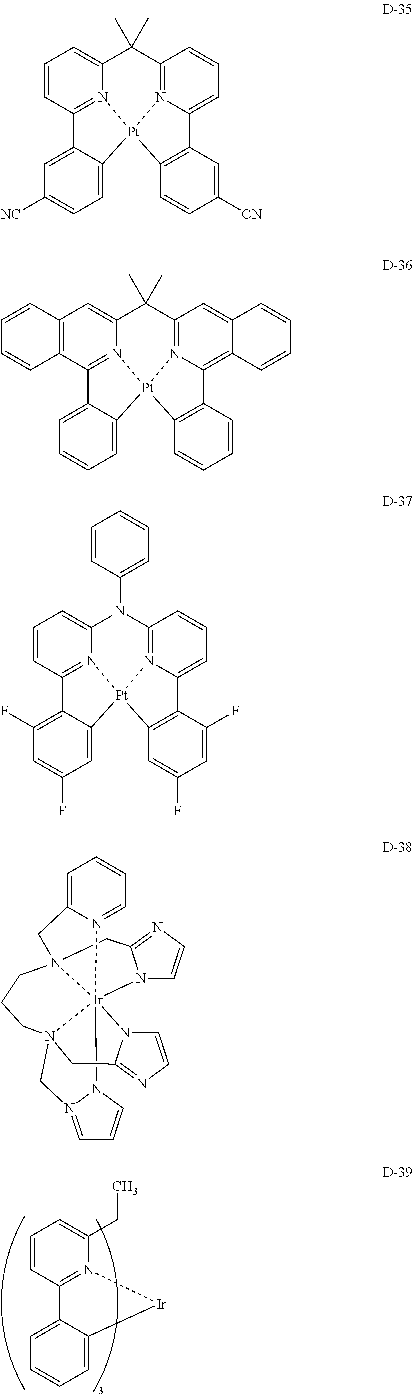

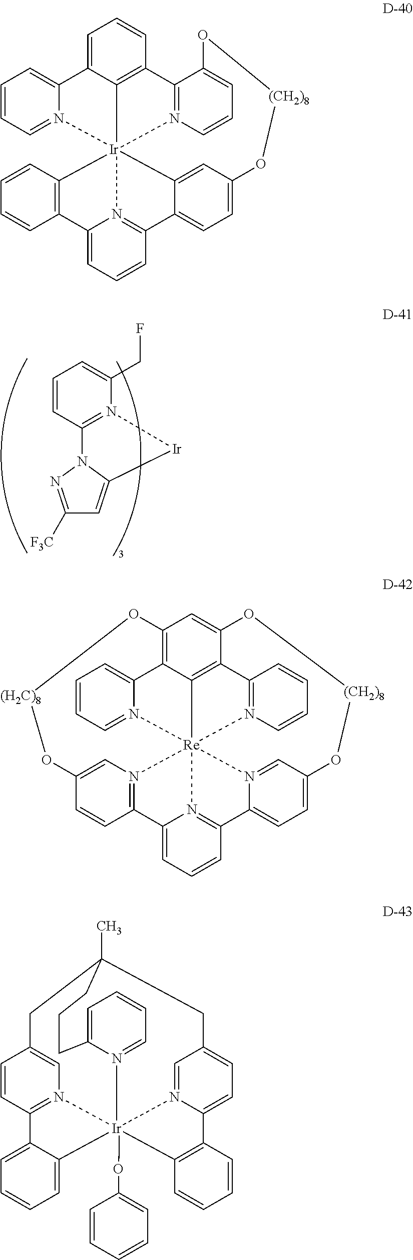

The light-emitting dopant is preferably contained in the light-emitting layer in an amount of 0.1% by mass to 50% by mass with respect to the total amount of the compounds generally forming the light-emitting layer. From the viewpoints of drive durability and external light-emission efficiency, it is more preferably contained in an amount of 1% by mass to 50% by mass, particularly preferably 2% by mass to 40% by mass.

Although the thickness of the light-emitting layer is not particularly limited, in general, it is preferably 2 nm to 500 nm preferred. From the viewpoint of external light-emission efficiency, it is more preferably 3 nm to 200 nm, particularly preferably 5 nm to 100 nm.

The host material may be hole transporting host materials excellent in hole transporting property (which may be referred to as a “hole transporting host”) or electron transporting host compounds excellent in electron transporting property (which may be referred to as an “electron transporting host”).

The hole transporting host materials are not particularly limited and may be appropriately selected depending on the intended purpose. Examples of the hole transporting host materials contained in the organic light-emitting layer include pyrrole, indole, carbazole, azaindole, azacarbazole, triazole, oxazole, oxadiazole, pyrazole, imidazole, thiophene, polyarylalkane, pyrazoline, pyrazolone, phenylenediamine, arylamine, amino-substituted chalcone, styrylanthracene, fluorenone, hydrazone, stilbene, silazane, aromatic tertiary amine compounds, styrylamine compounds, aromatic dimethylidine compounds, porphyrin compounds, polysilane compounds, poly(N-vinylcarbazole), aniline copolymers, conductive high-molecular-weight oligomers (e.g., thiophene oligomers and polythiophenes), organic silanes, carbon films and derivatives thereof.

Among them, indole derivatives, carbazole derivatives, aromatic tertiary amine compounds and thiophene derivatives are preferred. Also, compounds each containing a carbazole group in the molecule are more preferred. Further, compounds each containing a t-butyl-substituted carbazole group are particularly preferred.

The electron transporting host is not particularly limited and may be appropriately selected depending on the intended purpose. The electron transporting host to be used in the organic light-emitting layer preferably has an electron affinity Ea of 2.5 eV to 3.5 eV, more preferably 2.6 eV to 3.4 eV, particularly preferably 2.8 eV to 3.3 eV, from the viewpoints of improvement in durability and decrease in drive voltage. Also, it preferably has an ionization potential Ip of 5.7 eV to 7.5 eV, more preferably 5.8 eV to 7.0 eV, particularly preferably 5.9 eV to 6.5 eV, from the viewpoints of improvement in durability and decrease in drive voltage.

Examples of the electron transporting host include pyridine, pyrimidine, triazine, imidazole, pyrazole, triazole, oxazole, oxadiazole, fluorenone, anthraquinonedimethane, anthrone, diphenylquinone, thiopyrandioxide, carbodiimide, fluorenylidenemethane, distyrylpyradine, fluorine-substituted aromatic compounds, heterocyclic tetracarboxylic anhydrides (e.g., naphthalene and perylene), phthalocyanine, derivatives thereof (which may form a condensed ring with another ring) and various metal complexes such as metal complexes of 8-quinolynol derivatives, metal phthalocyanine, and metal complexes having benzoxazole or benzothiazole as a ligand.

The electron transporting host is not particularly limited and may be appropriately selected depending on the intended purpose. Preferred electron transporting hosts are metal complexes, azole derivatives (e.g., benzimidazole derivatives and imidazopyridine derivatives) and azine derivatives (e.g., pyridine derivatives, pyrimidine derivatives and triazine derivatives).

Among them, metal complexes are preferred in terms of durability. As the metal complexes (A), preferred are those containing a ligand which has at least one nitrogen atom, oxygen atom, or sulfur atom and which is coordinated with the metal.

The metal ion contained in the metal complex is not particularly limited and may be appropriately selected depending on the intended purpose. It is preferably a beryllium ion, a magnesium ion, an aluminum ion, a gallium ion, a zinc ion, an indium ion, a tin ion, a platinum ion or a palladium ion; more preferably is a beryllium ion, an aluminum ion, a gallium ion, a zinc ion, a platinum ion or a palladium ion; particularly preferably is an aluminum ion, a zinc ion or a palladium ion.

Although there are a variety of known ligands to be contained in the metal complexes, examples thereof include those described in, for example, “Photochemistry and Photophysics of Coordination Compounds” authored by H. Yersin, published by Springer-Verlag Company in 1987; and “YUHKI KINZOKU KAGAKU—KISO TO OUYOU—(Metalorganic Chemistry—Fundamental and Application—)” authored by Akio Yamamoto, published by Shokabo Publishing Co., Ltd. in 1982.

The ligand is preferably nitrogen-containing heterocyclic ligands (preferably having 1 to 30 carbon atoms, more preferably 2 to 20 carbon atoms, particularly preferably 3 to 15 carbon atoms). It may be a unidentate ligand or a bi- or higher-dentate ligand. Preferred are bi- to hexa-dentate ligands, and mixed ligands of bi- to hexa-dentate ligands with a unidentate ligand.

The ligand is not particularly limited and may be appropriately selected depending on the intended purpose. Examples of the ligand include azine ligands (e.g., pyridine ligands, bipyridyl ligands and terpyridine ligands); hydroxyphenylazole ligands (e.g., hydroxyphenylbenzoimidazole ligands, hydroxyphenylbenzoxazole ligands, hydroxyphenylimidazole ligands and hydroxyphenylimidazopyridine ligands); alkoxy ligands (those having preferably 1 to 30 carbon atoms, more preferably 1 to 20 carbon atoms, particularly preferably 1 to 10 carbon atoms, such as methoxy, ethoxy, butoxy and 2-ethylhexyloxy); and aryloxy ligands (those having preferably 6 to 30 carbon atoms, more preferably 6 to 20 carbon atoms, particularly preferably 6 to 12 carbon atoms, such as phenyloxy, 1-naphthyloxy, 2-naphthyloxy, 2,4,6-trimethylphenyloxy and 4-biphenyloxy).

Further examples of the ligand include heteroaryloxy ligands (those having preferably 1 to 30 carbon atoms, more preferably 1 to 20 carbon atoms, particularly preferably 1 to 12 carbon atoms, examples of which include pyridyloxy, pyrazyloxy, pyrimidyloxy and quinolyloxy); alkylthio ligands (those having preferably 1 to 30 carbon atoms, more preferably 1 to 20 carbon atoms, particularly preferably 1 to 12 carbon atoms, examples of which include methylthio and ethylthio); arylthio ligands (those having preferably 6 to 30 carbon atoms, more preferably 6 to 20 carbon atoms, particularly preferably 6 to 12 carbon atoms, examples of which include phenylthio); heteroarylthio ligands (those having preferably 1 to 30 carbon atoms, more preferably 1 to 20 carbon atoms, particularly preferably 1 to 12 carbon atoms, examples of which include pyridylthio, 2-benzimidazolylthio, 2-benzoxazolylthio and 2-benzothiazolylthio); siloxy ligands (those having preferably 1 to 30 carbon atoms, more preferably 3 to 25 carbon atoms, particularly preferably 6 to 20 carbon atoms, examples of which include a triphenylsiloxy group, a triethoxysiloxy group and a triisopropylsiloxy group); aromatic hydrocarbon anion ligands (those having preferably 6 to 30 carbon atoms, more preferably 6 to 25 carbon atoms, particularly preferably 6 to 20 carbon atoms, examples of which include a phenyl anion, a naphthyl anion and an anthranyl anion); aromatic heterocyclic anion ligands (those having preferably 1 to 30 carbon atoms, more preferably 2 to 25 carbon atoms, and particularly preferably 2 to 20 carbon atoms, examples of which include a pyrrole anion, a pyrazole anion, a triazole anion, an oxazole anion, a benzoxazole anion, a thiazole anion, a benzothiazole anion, a thiophene anion and a benzothiophene anion); and indolenine anion ligands. Among them, nitrogen-containing heterocyclic ligands, aryloxy ligands, heteroaryloxy groups, siloxy ligands, etc. are preferred, and nitrogen-containing heterocyclic ligands, aryloxy ligands, siloxy ligands, aromatic hydrocarbon anion ligands, aromatic heterocyclic anion ligands, etc. are more preferred.

Examples of the metal complex electron transporting host include compounds described in, for example, JP-A Nos. 2002-235076, 2004-214179, 2004-221062, 2004-221065, 2004-221068 and 2004-327313.

In the light-emitting layer, it is preferred that the lowest triplet excitation energy (T1) of the host material is higher than T1 of the phosphorescence light-emitting material, from the viewpoints of color purity, light-emission efficiency and drive durability.

Although the amount of the host compound added is not particularly limited and may be appropriately determined depending on the intended purpose, it is preferably 15% by mass to 95% by mass with respect to the total mass of the compounds forming the light-emitting layer, in terms of light emitting efficiency and drive voltage.

### —Hole-Injection Layer and Hole-Transport Layer—

The hole-injection layer and hole-transport layer are layers having the function of receiving holes from the anode or from the anode side and transporting the holes to the cathode side. Materials to be incorporated into the hole-injection layer or the hole-transport layer may be a low-molecular-weight compound or a high-molecular-weight compound.

Specifically, these layers preferably contain, for example, pyrrole derivatives, carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidine compounds, phthalocyanine compounds, porphyrin compounds, thiophene derivatives, organosilane derivatives and carbon.

Also, an electron-accepting dopant may be incorporated into the hole-injection layer or the hole-transport layer of the organic EL device. The electron-accepting dopant is not particularly limited, so long as it has electron accepting property and the function of oxidizing an organic compound, and may be appropriately selected depending on the intended purpose. The electron-accepting dopant may be, for example, an inorganic or organic compound.

Specific examples of the inorganic compound include metal halides (e.g., ferric chloride, aluminum chloride, gallium chloride, indium chloride and antimony pentachloride) and metal oxides (e.g., vanadium pentaoxide and molybdenum trioxide).

As the organic compounds, those having a substituent such as a nitro group, a halogen, a cyano group and a trifluoromethyl group; quinone compounds; acid anhydride compounds; and fullerenes may be preferably used.

In addition, there can be preferably used compounds described in, for example, JP-A Nos. 06-212153, 11-111463, 11-251067, 2000-196140, 2000-286054, 2000-315580, 2001-102175, 2001-160493, 2002-252085, 2002-56985, 2003-157981, 2003-217862, 2003-229278, 2004-342614, 2005-72012, 2005-166637 and 2005-209643.

Among them, preferred are hexacyanobutadiene, hexacyanobenzene, tetracyanoethylene, tetracyanoquinodimethane, tetrafluorotetracyanoquinodimethane, p-fluoranil, p-chloranil, p-bromanil, p-benzoquinone, 2,6-dichlorobenzoquinone, 2,5-dichlorobenzoquinone, 1,2,4,5-tetracyanobenzene, 1,4-dicyanotetrafluorobenzene, 2,3-dichloro-5,6-dicyanobenzoquinone, p-dinitrobenzene, m-dinitrobenzene, o-dinitrobenzene, 1,4-naphthoquinone, 2,3-dichloronaphthoquinone, 1,3-dinitronaphthalene, 1,5-dinitronaphthalene, 9,10-anthraquinone, 1,3,6,8-tetranitrocarbazole, 2,4,7-trinitro-9-fluorenone, 2,3,5,6-tetracyanopyridine and fullerene C60. More preferred are hexacyanobutadiene, hexacyanobenzene, tetracyanoethylene, tetracyanoquinodimethane, tetrafluorotetracyanoquinodimethane, p-fluoranil, p-chloranil, p-bromanil, 2,6-dichlorobenzoquinone, 2,5-dichlorobenzoquinone, 2,3-dichloronaphthoquinone, 1,2,4,5-tetracyanobenzene, 2,3-dichloro-5,6-dicyanobenzoquinone and 2,3,5,6-tetracyanopyridine. Particularly preferred is tetrafluorotetracyanoquinodimethane.

These electron-accepting dopants may be used alone or in combination. Although the amount of the electron-accepting dopant used depends on the type of material, the dopant is preferably used in an amount of 0.01% by mass to 50% by mass, more preferably 0.05% by mass to 20% by mass, particularly preferably 0.1% by mass to 10% by mass, with respect to the material of the hole-transport layer.

The thicknesses of the hole-injection layer and the hole-transport layer are each preferably 500 nm or less in terms of reducing drive voltage. The thickness of the hole-transport layer is preferably 1 nm to 500 nm, more preferably 5 nm to 200 nm, still more preferably 10 nm to 200 nm. The thickness of the hole-injection layer is preferably 0.1 nm to 200 nm, more preferably 0.5 nm to 100 nm, still more preferably 1 nm to 100 nm.

Each of the hole-injection layer and the hole-transport layer may have a single-layered structure made of one or more of the above-mentioned materials, or a multi-layered structure made of a plurality of layers which are identical or different in composition.

### —Electron-Injection Layer and Electron-Transport Layer—

The electron-injection layer and the electron-transport layer are layers having the functions of receiving electrons from the cathode or the cathode side and transporting the electrons to the anode side. The electron-injection materials or electron-transport materials for these layers may be low-molecular-weight or high-molecular-weight compounds.

Specific examples thereof include pyridine derivatives, quinoline derivatives, pyrimidine derivatives, pyrazine derivatives, phthalazine derivatives, phenanthroline derivatives, triazine derivatives, triazole derivatives, oxazole derivatives, oxadiazole derivatives, imidazole derivatives, fluorenone derivatives, anthraquinodimethane derivatives, anthrone derivatives, diphenylquinone derivatives, thiopyrandioxide derivatives, carbodiimide derivatives, fluorenylidenemethane derivatives, distyrylpyradine derivatives, aryl tetracarboxylic anhydrides such as perylene and naphthalene, phthalocyanine derivatives, metal complexes (e.g., metal complexes of 8-quinolinol derivatives, metal phthalocyanine, and metal complexes containing benzoxazole or benzothiazole as the ligand) and organic silane derivatives (e.g., silole).

The electron-injection layer or the electron-transport layer in the organic EL device of the present invention may contain an electron donating dopant.

The electron donating dopant to be introduced in the electron-injection layer or the electron-transport layer is not particularly limited, so long as it has an electron-donating property and a property for reducing an organic compound, and may be appropriately selected depending on the intended purpose. Preferred examples thereof include alkali metals (e.g., Li), alkaline earth metals (e.g., Mg), transition metals including rare-earth metals, and reducing organic compounds. Among the metals, those having a work function of 4.2 eV or less are particularly preferably used. Examples thereof include Li, Na, K, Be, Mg, Ca, Sr, Ba, Y, Cs, La, Sm, Gd and Yb. Also, examples of the reducing organic compounds include nitrogen-containing compounds, sulfur-containing compounds and phosphorus-containing compounds.

In addition, there may be used materials described in, for example, JP-A Nos. 06-212153, 2000-196140, 2003-68468, 2003-229278 and 2004-342614. These electron donating dopants may be used alone or in combination. The amount of the electron donating dopant used depends on the type of the material, but it is preferably 0.1% by mass to 99% by mass, more preferably 0.1% by mass to 80% by mass, particularly preferably 0.1% by mass to 70% by mass, with respect to the amount of the material of the electron transport layer.

The thicknesses of the electron-injection layer and the electron-transport layer are each preferably 500 nm or less in terms of reducing drive voltage. The thickness of the electron-transport layer is preferably 1 nm to 500 nm, more preferably 5 nm to 200 nm, particularly preferably 10 nm to 100 nm. The thickness of the electron-injection layer is preferably 0.1 nm to 200 nm, more preferably 0.2 nm to 100 nm, particularly preferably 0.5 nm to 50 nm.

Each of the electron-injection layer and the electron-transport layer may have a single-layered structure made of one or more of the above-mentioned materials, or a multi-layered structure made of a plurality of layers which are identical or different in composition.

### —Hole Blocking Layer—

The hole blocking layer is a layer having the function of preventing the holes, which is have been transported from the anode side to the light-emitting layer, from passing toward the cathode side, and may be provided as an organic compound layer adjacent to the light-emitting layer on the cathode side.

The compound forming the hole blocking layer is not particularly limited and may be appropriately selected depending on the intended purpose. Examples thereof include aluminum complexes (e.g., aluminum bis(2-methyl-8-quinonylphenolate) (BAlq), triazole derivatives and phenanthroline derivatives (e.g., BCP).

The thickness of the hole blocking layer is preferably 1 nm to 500 nm, more preferably 5 nm to 200 nm, particularly preferably 10 nm to 100 nm.

The hole blocking layer may have a single-layered structure made of one or more of the above-mentioned materials, or a multi-layered structure made of a plurality of layers which are identical or different in composition.

### —Electron Blocking Layer—

An electron blocking layer is a layer having the function of preventing the electrons, which have been transported from the cathode side to the light-emitting layer, from passing toward the anode side, and may be provided as an organic compound layer adjacent to the light-emitting layer on the anode side in the present invention.

Examples of the compound forming the electron blocking layer include those listed as a hole-transport material.

The thickness of the electron blocking layer is preferably 1 nm to 500 nm, more preferably 5 nm to 200 nm, particularly preferably 10 nm to 100 nm.

The electron blocking layer may have a single-layered structure made of one or more of the above-mentioned materials, or a multi-layered structure made of a plurality of layers which are identical or different in composition.

In order to improve the light-emission efficiency, the light-emitting layer may have such a configuration that charge generation layers are provided between a plurality of light-emitting layers.

The charge generation layer is a layer having the functions of generating charges (i.e., holes and electrons) when an electrical field is applied, and of injecting the generated charges into the adjacent layers.

The material for the charge generation layer is not particularly limited, so long as it has the above-described functions, and may be appropriately selected depending on the intended purpose. The charge generation layer may be made of a single compound or a plurality of compounds.

Specifically, the material may be those having conductivity, those having semi-conductivity (e.g., doped organic layers) and those having electrical insulating property. Examples thereof include the materials described in JP-A Nos. 11-329748, 2003-272860 and 2004-39617.

Specific examples thereof include transparent conductive materials (e.g., ITO and IZO (indium zinc oxide)), fullerenes (e.g., C60), conductive organic compounds (e.g., oligothiophene, metal phthalocyanine, metal-free phthalocyanine, metal porphyrins and non-metal porphyrins), metal materials (e.g., Ca, Ag, Al, Mg—Ag alloys, Al—Li alloys and Mg—Li alloys), hole conducting materials, electron conducting materials and mixtures thereof.

The hole conducting materials are not particularly limited and may be appropriately selected depending on the intended purpose. Examples thereof include hole transport organic materials (e.g., 4,4′,4″-tris(2-naphthylphenylamino)triphenylamine (2-TNATA) and N′-dinaphthyl-N,N′-diphenyl-[1,1′-biphenyl]-4,4′-diamine (NPD)) doped with an oxidant having an electron-attracting property (e.g., 2,3,5,6-tetrafluoro-7,7,8,8-tetracyanoquinodimethane (F4-TCNQ), TCNQ and FeCl₃), P-type conductive polymers and P-type semiconductors. Examples of the electron conducting materials include electron transport organic materials doped with a metal or metal compound having a work function lower than 4.0 eV, N-type conductive polymers and N-type semiconductors. Examples of the N-type semiconductors include N-type Si, N-type CdS and N-type ZnS. Examples of the P-type semiconductors include P-type Si, P-type CdTe and P-type CuO.

Also, the charge generation layer may be made of electrical insulating materials such as V₂O₅.

The charge generation layer may have a single-layered or multi-layered structure. Examples of the multi-layered structure the charge generation layer has include a structure in which a conductive material (e.g., transparent conductive materials and metal materials) is laminated on a hole or electron transport material, and a structure in which the above-listed hole conducting material is laminated on the above-listed electron conducting material.

In general, the thickness and material of the charge generation layer is preferably determined so that the transmittance thereof with respect to visible light is 50% or higher. The thickness thereof is not particularly limited and may be appropriately determined depending on the intended purpose. The thickness is preferably 0.5 nm to 200 nm, more preferably 1 nm to 100 nm, still more preferably 3 nm to 50 nm, particularly preferably 5 nm to 30 nm.

The forming method for the charge generation layer is not particularly limited. The above-described forming methods for the organic compound layer may be employed.

The charge generation layer is formed between two or more layers of the above light-emitting layer. The charge generation layer may contain, at the anode or cathode side, a material having the function of injecting charges into the adjacent layers. In order to increase injectability of electrons into the adjacent layers at the anode side, electron injection compounds (e.g., BaO, SrO, Li₂O, LiCl, LiF, MgF₂, MgO and CaF₂) may be deposited on the charge generation layer at the anode side.

In addition to the above-listed materials, the material for charge generation layer may be selected from those described in JP-A No. 2003-45676, and U.S. Pat. Nos. 6,337,492, 6,107,734 and 6,872,472.

### <<Electrode>>

In the present invention, the electrode is not particularly limited, so long as it can apply an electrical field to the light-emitting layer, and may be appropriately selected depending on the intended purpose. The electrode may be appropriately an anode or cathode, or transparent or semi-transparent in consideration of its position in the organic EL element. For example, the electrode located in the light-emitting direction from the light-emitting layer of the organic EL element may be transparent.

### —Anode—

The anode may be transparent or opaque, or have reflectivity, so long as it has the function of serving as an electrode that supplies holes to the organic light-emitting layers constituting the organic compound layer. When the cathode is transparent or semi-transparent, the anode has preferably reflectivity in view that light is efficiently extracted from the cathode. The shape, structure, size, etc. thereof are not particularly limited and may be appropriately selected from known electrode materials depending on the application/purpose of the organic EL element.

The materials for the anode are not particularly limited and may be appropriately selected depending on the intended purpose. Examples thereof include metals, alloys, metal oxides, conductive compounds and mixtures thereof. Specific examples include conductive metal oxides such as tin oxides doped with, for example, antimony and fluorine (ATO and FTO); tin oxide, zinc oxide, indium oxide, indium tin oxide (ITO) and indium zinc oxide (IZO); metals such as gold, silver, chromium, nickel and aluminum; mixtures or laminates of these metals and the conductive metal oxides; inorganic conductive materials such as copper iodide and copper sulfide; organic conductive materials such as polyaniline, polythiophene and polypyrrole; and laminates of these materials and ITO. Among them, metal materials having high reflectivity are preferred. In particular, silver and aluminum are preferred from the viewpoints of productivity, high conductivity, transparency, etc.

The anode may be formed on the substrate by a method which is appropriately selected from wet methods such as printing methods and coating methods; physical methods such as vacuum deposition methods, sputtering methods and ion plating method; and chemical methods such as CVD and plasma CVD methods, in consideration of suitability for the material for the anode. For example, when ITO is used as a material for the anode, the anode may be formed in accordance with a DC or high-frequency sputtering method, a vacuum deposition method, or an ion plating method.

In the present invention, a position at which the anode is to be disposed is not particularly limited, so long as the anode is provided so as to come into contact with the organic compound layer. The position may be appropriately determined depending on the application/purpose of the organic EL element. The anode may be entirely or partially formed on one surface of the organic compound layer.

Patterning for forming the anode may be performed by a chemical etching method such as photolithography; a physical etching method such as etching by laser; a method of vacuum deposition or sputtering using a mask; a lift-off method; or a printing method.

The thickness of the anode may be appropriately selected depending on the material for the anode and is, therefore, not definitely determined. It is generally about 10 nm to about 50 μm, preferably 50 nm to 20 μm.

The resistance of the anode is preferably 10³ Ω/square or less, more preferably 10² Ω/square or less. When the anode has reflectivity, the reflectance is preferably 60% or higher, more preferably 70% or higher, in view that light is emitted from the transparent or semi-transparent anode.

### —Cathode—

In general, the cathode may be any material so long as it has the function of serving as an electrode which injects electrons into the organic light-emitting layers constituting the above organic compound layer. The shape, structure, size, etc. thereof are not particularly limited and may be appropriately selected from known electrode materials depending on the application/purpose of the organic EL element.

The materials for the cathode are not particularly limited and may be appropriately selected depending on the intended purpose. Examples thereof include metals, alloys, metal oxides, conductive compounds and mixtures thereof. Specific examples thereof include alkali metals (e.g., Li, Na, K and Cs), alkaline earth metals (e.g., Mg and Ca), gold, silver, lead, aluminum, sodium-potassium alloys, lithium-aluminum alloys, magnesium-silver alloys and rare earth metals (e.g., indium and ytterbium). These may be used individually, but it is preferred that two or more of them are used in combination from the viewpoint of satisfying both stability and electron-injection property.

Among them, as the materials for forming the cathode, alkali metals or alkaline earth metals are preferred in terms of excellent electron-injection property, and materials containing silver as a major component are preferred in terms of excellent storage stability. The term “material containing silver as a major component” refers to a material composed of silver alone; alloys containing silver and 0.01% by mass to 10% by mass of an alkali or alkaline earth metal; or the mixtures thereof (e.g., magnesium-silver alloys).

The materials for the cathode are described in detail in JP-A Nos. O₂-15595 and 05-121172. The materials described in these literatures can be used in the present invention.

The method for forming the cathode is not particularly limited, and the cathode may be formed by a known method. For example, the cathode may be formed by a method which is appropriately selected from wet methods such as printing methods and coating methods; physical methods such as vacuum deposition methods, sputtering methods and ion plating methods; and chemical methods such as CVD and plasma CVD methods, in consideration of suitability for the material for the cathode. For example, when a metal (or metals) is (are) selected as a material (or materials) for the cathode, one or more of them may be applied simultaneously or sequentially by a sputtering method.

Patterning for forming the cathode may be performed by a chemical etching method such as photolithography; a physical etching method such as etching by laser; a method of vacuum deposition or sputtering using a mask; a lift-off method; or a printing method.

In the present invention, a position at which the cathode is to be disposed is not particularly limited, so long as the cathode can apply an electric field to the light-emitting layer. The cathode may be entirely or partially formed on the light-emitting layer.

Furthermore, a dielectric layer having a thickness of 0.1 nm to 5 nm and being made, for example, of fluorides and oxides of an alkali or alkaline earth metal may be inserted between the cathode and the organic compound layer. The dielectric layer may be considered to be a kind of electron-injection layer. The dielectric layer may be formed by, for example, a vacuum deposition method, a sputtering method and an ion plating method.

The thickness of the cathode may be appropriately selected depending on the material for the cathode and is, therefore, not definitely determined. It is generally about 10 nm to about 5 μm, and preferably 20 nm to 1 μm.

Moreover, the cathode may be transparent, semi-transparent or opaque. The transparent cathode may be formed as follows. Specifically, a 1 nm- to 20 nm-thick thin film is formed from a material for the cathode, and a transparent conductive material (e.g., ITO and IZO) is laminated on the thus-formed film.

### <<Substrate>>

The organic EL element of the present invention may contain a substrate for the purpose of supporting the element. The substrate is not particularly limited so long as it can support the element. The shape, structure, size, material, etc. of the substrate may be appropriately determined. The substrate may be formed as the light-extracting substrate of the above light-extraction member.

### <Other Members>

### <<Seal Layer>>

In order to prevent water permeation from outside, the organic EL element may contain a seal layer. The seal layer is not particularly limited and may be appropriately selected depending on the intended purpose. The seal layer may be a single-layered or multi-layered structure made of various inorganic compounds or organic compounds. Examples of the inorganic compound include SiNx, SiON, SiO₂, Al₂O₃ and TiO₂. Examples of the organic compound include silicone polymers, epoxy polymers, acrylic polymers and urethane polymers. The thickness of the seal layer is not particularly limited and may be appropriately determined is depending on the intended purpose. The thickness is preferably adjusted to 1 μm to 10 μm, more preferably 1.5 μm to 7 μm, particularly preferably 3 μm to 5 μm. The seal layer having a thickness smaller than 1 μm may not exhibit sufficient sealing function of preventing permeation of oxygen and water contained in the air. When the seal layer having a thickness greater than 10 μm is used, light transmittance decreases to potentially degrade transparency. Regarding optical characteristics of the seal layer, the light transmittance is preferably 80% or higher, more preferably 85% or higher, particularly preferably 90% or higher. The method of forming the seal layer is not particularly limited and may be appropriately selected depending on the intended purpose. Examples thereof include a CVD method and a vacuum vapor deposition method.

### (Method for Producing Organic EL Element)

A method of the present invention for producing an organic EL element includes a step of forming a light-extraction member, a step of forming a light-emitting part and a bonding step; and, if necessary, includes other steps.

### <Process of Forming Light-Extraction Member (Light-Extraction Member-Forming Process)>

The light-extraction member-forming process is not particularly limited, so long as the light-extraction member having the light-extracting substrate, the color filter layer and the lens member can be formed, and may be appropriately selected depending on the intended purpose. The light-extraction member-forming process is preferably a process as illustrated in FIGS. 3A to 3C in view that the organic EL element is not adversely affected due to, for example, heat. Specifically, in this process, the lens member 12 is formed on an appropriate substrate such as a temporary-bonding substrate 56 made of metal or glass (a lens member forming-step); the lens member is bonded (a bonding step) to the color filter layer 16 which has previously been formed on the light-extracting substrate 20 (a color filter layer-forming step); and the temporary-bonding substrate 56 is separated from the lens member bonded to the color filter layer 16 (a separating step). Next, description will be given with respect to this process.

### <<Lens Member-Forming Step>>

The lens member-forming step is not particularly limited, so long as the lens member is formed on the temporary-bonding substrate, and may be appropriately determined depending on the intended purpose. The lens member-forming step is performed by, for example, a spin coat method, a screen printing method or a dispenser method. In one employable method as illustrated in FIG. 3A, a coating liquid containing materials for the lens member 12 is applied onto the temporary-bonding substrate 56, and a lens member-forming mold 52 having a predetermined shape is used through imprinting to form the lens members 12. In the lens member-forming step, a temporary-bonding sheet 54, whose surface has been treated with fluorine, may be formed on the temporary-bonding substrate 56 so that the lens member 12 can be easily separated from the temporary-bonding substrate 56 after the lens member 12 has been formed on the temporary-bonding substrate 56. In this case, the coating liquid for the lens member may be applied onto the temporary-bonding sheet 54 and treated similar to the above. Also, depending on the materials for the lens member, the coating liquid (for the lens member 12) applied onto the temporary-bonding substrate 56 may be cured through application of appropriate energy such as UV rays and heat so that the applied coating liquid has an appropriate strength. In addition, an adhesive may be applied onto the convex top portion 13 so that the color filter layer 16 can be bonded to the convex top portion 13 of the lens member 12 in the below-described bonding step. In this manner, the lens member 12 is formed on the temporary-bonding substrate 56.

### <<Color Filter Layer-Forming Step>>

The color filter layer-forming step is not particularly limited, so long as the color filter layer can be formed on the light-extracting substrate, and may be appropriately selected depending on the intended purpose. For example, the color filter layer 16 may be formed on the light-extracting substrate 20 by an appropriate method such as a lithography method, an etching method or an inkjet method. In the color filter layer-forming step, the adhesive portion 18 may be formed on the color filter layer 16 in order for the color filter layer to be bonded to the lens member formed in the above lens member-forming step. The method for forming the adhesive portion 18 is not particularly limited, so long as the material of the adhesive portion 18 can be applied on necessary portions for bonding of the lens member 12 in consideration of, for example, necessary strength, and may be appropriately determined depending on the intended purpose. For example, a coating liquid containing the materials for the adhesive portion 18 may be applied onto the formed color filter layer 16 by, for example, an inkjet method or a spin coat method, to thereby form an adhesive portion in the form of layer. Also, the adhesive portion 18 may be formed so that the color filter layer has an adhesion function. In this manner, the color filter layer 16 is formed on the light-extracting substrate 20.

### <<Bonding Step>>

The bonding step is not particularly limited, so long as the color filter layer can be bonded to the convex top portion of the lens member via the adhesive portion, and may be appropriately selected depending on the intended purpose. Specifically, the bonding step may be performed by a method in which the lens member (formed in the above lens member-forming step) and the color filter layer (formed in the above color filter layer-forming step) are bonded to each other so that the color filter layer 16 is bonded to the convex top portion 13 of the lens member 12. The position at which the lens member and the color filter layer are bonded to each other is not particularly limited, so long as the convex top portion 13 and the color filter layer 16 can be bonded to each other via the adhesive portion 18, and may be appropriately determined depending on the intended purpose. From the viewpoint of increasing light-extraction efficiency, the lens member and the color filter layer are preferably bonded to each other at positions where each convex top portion 13 corresponds to each pixel. For example, as illustrated in FIG. 3B, the convex top portions may be disposed so as to come into contact with blue, green and red filter portions.

### <<Separating Step>>

The separating step is not particularly limited, so long as the temporary-bonding substrate can be separated from the lens member bonded to the color filter layer in the above bonding step, and may be appropriately determined depending on the intended purpose. After the lens member 12 has been bonded to the color filter layer 16 in the bonding step, the temporary-bonding substrate 56 may be downwardly separated from the lens member 12 in a direction indicated by the arrow in FIG. 3B. When the temporary-bonding substrate 56 is separated, a flat portion 14 of the lens member 12 (on the temporary-bonding substrate 56) is obtained.

In this manner, the light-extraction member, having the light-extracting substrate, the color filter layer and the lens member, is formed.

### <Step of Forming Light-Emitting Part (Light-Emitting Part-Forming Step)>

The light-emitting part-forming step is not particularly limited, so long as the light-emitting part containing at least a pair of electrodes on a substrate and a light-emitting layer disposed between the electrodes can be formed, and may be appropriately determined depending on the intended purpose. A light-emitting part 50 containing a pair of electrodes 32 and 33 and an organic compound layer 34 disposed between the electrodes may be formed by, for example, a dry film-forming method (e.g., a vapor deposition method and a sputtering method), a transfer method, a printing method, a coating method, an inkjet method or a spray method. In the light-emitting part-forming step, an appropriate joining layer may be provided on the top portion of each electrode so that the light-extraction member formed as described above is joined with the electrodes. For example, as illustrated in FIG. 3C, a seal adhesive layer 38 may have the function of the joining layer. In this manner, the light-emitting part is formed.

### <Joining Step>

The joining step is not particularly limited, so long as the light-extraction member can be joined with the light-emitting part, and may be appropriately determined depending on the intended purpose. For example, as illustrated in FIG. 3C, the light-extraction member 10 (formed in the above light-extraction member-forming process) and the light-emitting part 50 (formed in the above light-emitting part-forming step) may be joined with each other so that the flat portion 14 of the lens member 12 is joined with the seal adhesive layer 38 on the seal layer 36 of the light-emitting part 50. Joining is preferably performed in an inert atmosphere containing, for example, nitrogen, helium or argon so that the constituent components of the organic EL element is not adversely affected due to, for example, oxygen contained in the air. The manner in which joining is performed is not particularly limited and may be appropriately determined depending on the intended purpose. From the viewpoint of increasing light-extraction efficiency, the light-extraction member and the light-emitting part may be joined with each other so that colors (red, green and blue) of lights emitted from the organic compound layer 34 correspond to a red filter portion 16r, a green filter portion 16g and a blue filter portion 16b contained in the color filter layer 16. For example, a red filter portion may be disposed in the optical path of red light emitted from the organic compound layer, a green filter portion in the optical path of green light, and a blue filter portion in the optical path of blue light. In this manner, the light-extraction member 10 is joined with the light-emitting part 50 to produce an organic EL element.

### EXAMPLES

The present invention will next be described in detail by way of Examples and Comparative Examples given below, but should not be construed as being limited to Examples.

### Example 1

### Formation of Light-Emitting Part

As described below, a hole injection layer, a hole transport layer, a blue light-emitting layer, a green light-emitting layer, a red light-emitting layer, an electron transport layer, an electron injection layer and an upper electrode layer were formed in this order over a reflective electrode layer (Al) on a TFT (active matrix) substrate.

### (Green Organic Compound Layer)

A hole injection layer was formed on the reflective electrode layer (anode) by vacuum-depositing 2-TNATA [4,4′,4″-tris(2-naphthylphenylamino)triphenylamine] and MnO₃ at a ratio of 7:3 so as to have a thickness of 20 nm.

Next, a first hole transport layer was formed on the hole injection layer by vacuum-depositing 2-TNATA doped with F4-TCNQ is (2,3,5,6-tetrafluoro-7,7,8,8-tetracyanoquinodimethane) at a concentration of 1.0% so as to have a thickness of 141 nm.

Next, a second hole transport layer was formed on the first hole transport layer by vacuum-depositing α-NPD [N,N′-(dinaphthylphenylamino)pyrene] so as to have a thickness of 10 nm.

Next, a third hole transport layer was formed on the second hole transport layer by vacuum-depositing hole transport material A having the following structural formula so as to have a thickness of 3 nm.

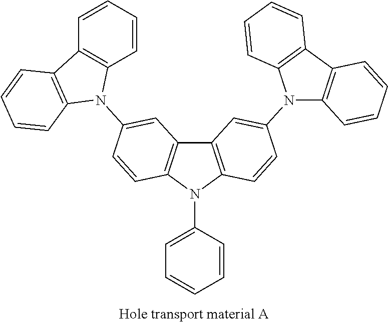

Next, a light-emitting layer was formed on the third hole transport layer by vacuum-depositing CBP (4,4′-dicarbazole-biphenyl) serving as a host material and light-emitting material G having the following structural formula at a ratio of 85:15 so as to have a thickness of 20 nm.

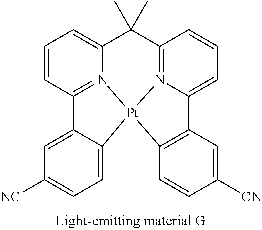

Next, a first electron transport layer was formed on the light-emitting layer by vacuum-depositing BAlq (aluminum(III) bis(2-methyl-8-quinolinato)-4-phenylphenolate) so as to have a thickness of 39 nm.

Next, a second electron transport layer was formed on the first electron transport layer by vacuum-depositing BCP (2,9-dimethyl-4,7-diphenyl-1,10-phenanthroline) so as to have a thickness of 1 nm.

Next, a first electron injection layer was formed on the second electron transport layer by vacuum-depositing LiF so as to have a thickness of 1 nm.

Next, a second electron injection layer was formed on the first electron injection layer by vacuum-depositing Al so as to have a thickness of 0.5 nm.

Next, a cathode was formed on the second electron injection layer by vacuum-depositing silver (Ag) so as to have a thickness of 20 nm.

### (Red Organic Compound Layer)

A hole injection layer was formed on the reflective electrode layer (anode) by vacuum-depositing 2-TNATA [4,4′,4″-tris(2-naphthylphenylamino)triphenylamine] and MnO₃ at a ratio of 7:3 so as to have a thickness of 20 nm.

Next, a first hole transport layer was formed on the hole injection layer by vacuum-depositing 2-TNATA doped with F4-TCNQ at a concentration of 1.0% so as to have a thickness of 196 nm.

Next, a second hole transport layer was formed on the first hole transport layer by vacuum-depositing α-NPD [N,N′-(dinaphthylphenylamino)pyrene] so as to have a thickness of 10 nm.

Next, a light-emitting layer was formed on the second hole transport layer by co-depositing in vacuum BAlq serving as a host material and light-emitting material R having the following structural formula at a ratio of 95:5 so as to have a thickness of 30 nm.

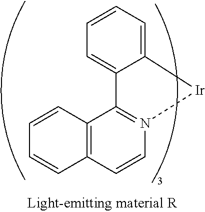

Next, a first electron transport layer was formed on the light-emitting layer by vacuum-depositing BAlq so as to have a thickness of 48 nm.

Next, a second electron transport layer was formed on the first electron transport layer by vacuum-depositing BCP so as to have a thickness of 1 nm.

Next, a first electron injection layer was formed on the second electron transport layer by vacuum-depositing LiF so as to have a thickness of 1 nm.

Next, a second electron injection layer was formed on the first electron injection layer by vacuum-depositing Al so as to have a thickness of 0.5 nm.

Next, a cathode was formed on the second electron injection layer by vacuum-depositing silver (Ag) so as to have a thickness of 20 nm.

### (Blue Organic Compound Layer)

A hole injection layer was formed on the reflective electrode layer (anode) by vacuum-depositing 2-TNATA [4,4′,4″-tris(2-naphthylphenylamino)triphenylamine] and MnO₃ at a ratio of 7:3 so as to have a thickness of 20 nm.

Next, a first hole transport layer was formed on the hole injection layer by vacuum-depositing 2-TNATA doped with F4-TCNQ at a concentration of 1.0% so as to have a thickness of 110 nm.

Next, a second hole transport layer was formed on the first hole transport layer by vacuum-depositing α-NPD [N,N′-(dinaphthylphenylamino)pyrene] so as to have a thickness of 10 nm.

Next, a third hole transport layer was formed on the second hole transport layer by vacuum-depositing hole transport material A having the following structural formula so as to have a thickness of 3 nm.

Next, a light-emitting layer was formed on the third hole transport layer by vacuum-depositing mCP (1,3-bis(carbazolyl)benzene) serving as a host material and light-emitting material B having the following structural formula at a ratio of 85:15 so as to have a thickness of 30 nm.

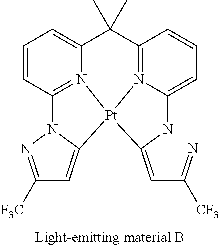

Next, a first electron transport layer was formed on the light-emitting layer by vacuum-depositing BAlq so as to have a thickness of 29 nm.

Next, a second electron transport layer was formed on the first electron transport layer by vacuum-depositing BCP so as to have a thickness of 1 nm.

Next, a first electron injection layer was formed on the second electron transport layer by vacuum-depositing LiF so as to have a thickness of 1 nm.

Next, a second electron injection layer was formed on the first electron injection layer by vacuum-depositing Al so as to have a thickness of 0.5 nm.

Next, a cathode was formed on the second electron injection layer by vacuum-depositing silver (Ag) so as to have a thickness of 20 nm.

A 5 μm-thick SiON layer serving as a seal layer was formed on the upper electrode obtained in this manner. Notably, the SiON layer was formed so as to cover light-emitting parts as illustrated in FIG. 1.

The same resin material as in a lens member of the below-described light-extraction member was applied on the thus-formed seal layer so as to have a thickness of 1 μm, whereby light-emitting parts were formed.

### <Formation of Light-Extraction Member>

### [Formation of Lens Member]

A lens member coating liquid containing the following components was applied on a temporary-bonding substrate.

PAK-01-CL (product of Toyo Gosei Co. Ltd.)

SILPOT 184 (product of Dow Corning Toray)

After application of the lens member coating liquid, a quartz mold having a predetermined dimension was pressed against the resultant coating film, followed by irradiating with UV rays through the mold, to thereby form hemispherical lenses (diameter of each hemispherical lens: 200 μm, refractive index: 1.52) serving as a lens member.

### [Formation of Color Filter Layer]

Separately, black color resist CK-8400 (product of FUJIFILM Electronics Materials Co., Ltd.) was applied by a spin coater onto the light-extracting substrate so as to have a thickness (after drying) of 1.0 μm, followed by drying at 120° C. for 2 min, to thereby form a uniform black coating film.

Next, using an exposing device, the resultant coating film was irradiated through a 100 μm-thick mask with light having a wavelength of 365 nm at an exposure dose of 300 mJ/cm². After irradiation, the exposed film was developed with a developer of 10% CD-1 (product of FUJIFILM Electronics Materials Co., Ltd.) at 26° C. for 90 sec. Subsequently, the developed film was rinsed with running water for 20 sec, dried with an air knife, and thermally treated at 220° C. for 60 min, to thereby form a black matrix pattern (image).

Next, the following three color curable compositions were dispersed with a sand mill for one day. Notably, the green color dispersion liquid may be referred to as dispersion liquid (A-1), the red color dispersion liquid as dispersion liquid (A-2), and the blue color dispersion liquid as dispersion liquid (A-3).

### [Green Color: Dispersion Liquid (A-1)]

Benzyl methacrylate/methacrylic acid copolymer: 80 parts by mass
(weight average molecular weight: 30,000, acid value: 120)
Propylene glycol monomethyl ether acetate: 500 parts by mass
Copper phthalocyanine pigment: 33 parts by mass
C. I. Pigment Yellow 185: 67 parts by mass

### [Red Color: Dispersion Liquid (A-2)]

Benzyl methacrylate/methacrylic acid copolymer: 80 parts by mass
(weight average molecular weight: 30,000, acid value: 120)
Propylene glycol monomethyl ether acetate: 500 parts by mass
Pigment Red 254: 50 parts by mass
Pigment Red PR177: 50 parts by mass

### [Blue Color: Dispersion Liquid (A-3)]

Benzyl methacrylate/methacrylic acid copolymer: 80 parts by mass
(weight average molecular weight: 30,000, acid value: 120)
Propylene glycol monomethyl ether acetate: 500 parts by mass
Pigment Blue 15:6: 95 parts by mass
Pigment Violet 23: 5 parts by mass

Next, the following components were added to 60 parts by mass of each of the above color curable compositions (i.e., dispersion liquids (A-1), (A-2) and (A-3)), to thereby obtain compositions of every color.

Dipentaerythritol hexaacrylate (DPHA): 80 parts by mass
4[o-Bromo-p-N,N-di(ethoxycarbonyl)aminophenyl]2,6-di(trichloromethyl)-S-triazine: 5 parts by mass
7-[{4-Chloro-6-(diethylamino)-S-triazin-2-yl}amino]-3-phenylcoumalin: 2 parts by mass
Hydroquinone monomethyl ether: 0.01 parts by mass
Propylene glycol monomethyl ether acetate: 500 parts by mass

The above-prepared compositions for each color were homogeneously mixed and then filtrated with a filter having a pore size of 5 μm, to thereby obtain three color curable compositions of the present invention. Of these, the green curable composition was applied by a spin coater onto the glass substrate, on which the black matrix had been formed, so as to have a thickness (after drying) of 1.0 μm, followed by drying at 120° C. for 2 min, to thereby form a uniform green coating film.

Next, using an exposing device, the resultant coating film was irradiated through a 100 μm-thick mask with light having a wavelength of 365 nm at an exposure dose of 300 mJ/cm². After irradiation, the exposed film was developed with a developer of 10% CD-1 (product of FUJIFILM Electronics Materials Co., Ltd.) at 26° C. for 60 sec. Subsequently, the developed film was rinsed with running water for 20 sec, dried with an air knife, and thermally treated at 220° C. for 60 min, to thereby form a patterned green image (green pixels). In the same manner as in the green curable composition, each of the red curable composition and the blue curable composition was applied to the same glass substrate, to thereby sequentially form a patterned red image (red pixels) and a patterned blue image (blue pixels).

The same material as in the lens member (PAK-01-CL (product of Toyo Gosei Co. Ltd.)) was applied onto the thus-formed pattern so as to form an adhesive portion 18 having a thickness of 10 μm, to thereby fabricate a color filter layer on the light-extracting substrate.

### [Bonding]

The color filter layer was bonded to the convex top portions of the lens members, followed by irradiating with UV rays, to thereby cure the adhesive portion 18. After that, the temporary-bonding substrate was separated from the lens member to obtain a light-extraction member.

<Joining of Light-Extraction Member with Light-Emitting Part>

The thus-obtained light-extraction member and the light-emitting part were joined with each other in a nitrogen atmosphere so that the lens member surface from which the substrate had been separated (flat portion) was brought into contact with the seal adhesive layer of the light-emitting part, followed by curing, to thereby obtain organic EL element 1. Note that the light-extracting substrate had a water permeability of 0.000001 g/m²/day.

### Example 2

The procedure of Example 1 was repeated, except that the same material as each color material for the color filter layer was applied on the pattern of the color filter layer instead of the same material as in the lens member, to thereby obtain organic EL element 2. Note that the light-extracting substrate had a water permeability of 0.000001 g/m²/day.

### Example 3

The procedure of Example 1 was repeated, except that a barrier film (trade name: TECHBARRIER HX (product of MITSUBISHI PLASTICS) having a layer structure illustrated in FIG. 2 was used as the light-extracting substrate used for forming the light-extraction member (the substrate used for forming the color filter layer), to thereby obtain organic EL element 3. Note that the light-extracting substrate had a water permeability of 0.001 g/m²/day.

### Comparative Example 1

The procedure of Example 1 was repeated, except that no color filter layer was formed, to thereby obtain comparative organic EL element 1.

### Example 4

The procedure of Example 1 was repeated, except that the light-emitting part and the light-extraction member were not separately formed, and the lens member coating liquid and the materials for the color filter layer used for forming the light-extraction member were applied onto the seal adhesive layer and the resin layer (thickness: 1 μm) formed thereon in the formation of the light-emitting part. Notably, this Example is Example in terms of the organic EL element of the present invention, but is not the best mode. Also, this Example is Comparative Example in terms of the method of the present invention for producing an organic EL element.

### Example 5

The procedure of Example 1 was repeated, except that a light-extraction member was formed as follows, to thereby obtain organic EL element 5.

### [Formation of Lens Member]

A lens member coating liquid containing the following components was applied on a glass substrate having no temporary-bonding sheet.

PAK-01-CL (product of Toyo Gosei Co. Ltd.)

SILPOT 184 (product of Dow Corning Toray)

After application of the lens member coating liquid, a quartz mold having a predetermined dimension was pressed against the resultant coating film, followed by irradiating with UV rays through the mold and post-baking, to thereby form hemispherical lenses (diameter of each hemispherical lens: 200 μm, refractive index: 1.52) serving as a lens member (FIG. 3A).

### [Formation of Color Filter Layer]

Next, a color filter layer was formed in the same manner as in Example 1 (FIG. 3B).

### [Bonding]

The color filter layer was bonded to the convex top portions of the lens member, followed by irradiating with UV rays, to thereby cure the adhesive portion 18. After that, the glass substrate having no temporary-bonding sheet was separated from the lens member to obtain a light-extraction member (FIG. 4C). In this separation, the glass substrate having no temporary-bonding sheet was not smoothly separated from the lens member, and as a result, concave and convex portions were formed in the bottoms of the hemispherical lenses.

The thus-obtained light-extraction member was joined with the light-emitting part at the seal adhesive layer (UV-curable resin layer), to thereby obtain organic EL element 6. The thus-obtained organic EL element 6 had spaces (gaps) between the light-extraction member and the seal adhesive layer (UV-curable resin layer) (FIG. 4).

The spaces (gaps) formed low-refractive-index layers in a series of the hemispherical lenses, the seal adhesive layer (UV-curable resin layer) and the organic EL layers. As a result, the amount of light totally reflected between the spaces (gaps) and the seal adhesive layer (UV-curable resin layer) became large, and thus the light-extraction efficiency decreased (note that the bleeding and contrast thereof were the same levels as in the other organic EL elements).

### Example 6

The procedure of Example 1 was repeated, except that the thickness of the adhesive portion 18 made of the same material as in the lens member (PAK-01-CL (product of Toyo Gosei Co. Ltd.)) was changed from 10 μm to 200 μm, to thereby obtain organic EL element 6.

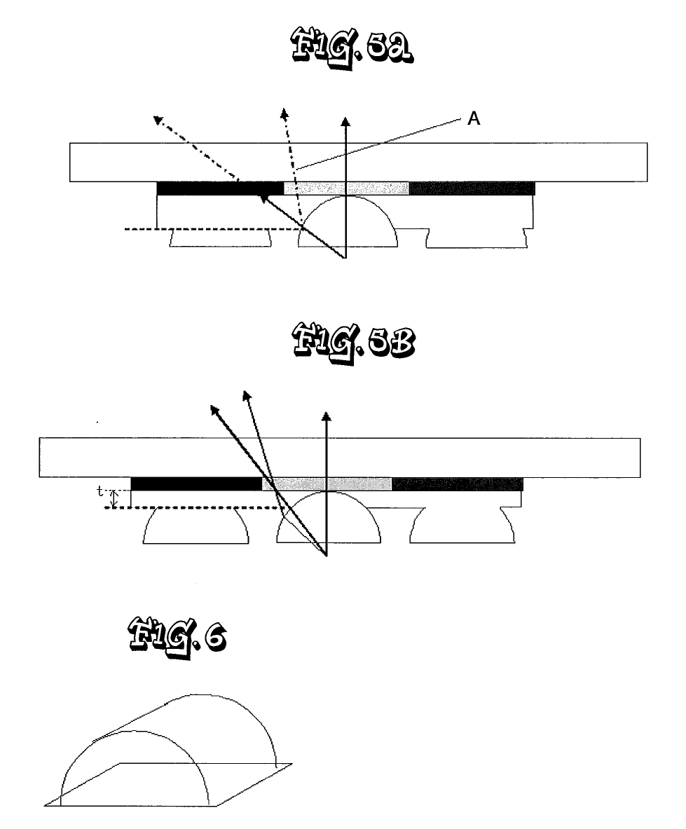

In the thus-obtained organic EL element 6, almost no space was present between the lens member and the color filter layer since the adhesive portion 18 was thick (FIG. 5A). Notably, in FIG. 5A, the symbol “A” denotes an optical path through which light passes in the case where a space is present between the lens member and the color filter layer.

Since the adhesive portion 18 and each lens have the same refractive index, the lens could not refract (collect) light satisfactorily, resulting in that the amount of light emitted from each pixel to the corresponding filter was decreased. Thus, the amount of light in each pixel was greatly decreased, although the contrast performance of the filter was not greatly changed.

Notably, in FIG. 5B, the symbol “t” denotes the largest thickness of the adhesive portion 18 through which light can pass via a lens lacking its intrinsic effect.

When the thickness of the adhesive portion is thin, the amount of light is not decreased. When the thickness of the adhesive portion is thick, the amount of light is decreased.

### Example 7

The procedure of Example 1 was repeated, except that the hemispherical lenses (serving as a lens member) were changed to cylindrical lenses (FIG. 6) (maximum height: 10 μm, width: 20 μm, refractive index: 1.52), to thereby obtain organic EL element 7.

Since the cylindrical lenses were decreased in light-extraction efficiency as compared with the hemispherical lenses, organic EL element 7 was also decreased in brightness as compared with other organic EL elements using the hemispherical lenses. The contrast of the element was not greatly changed.

### Example 8

The procedure of Example 3 was repeated, except that the barrier film (trade name: TECHBARRIER HX (product of MITSUBISHI PLASTICS)) was changed to a 0.1 mm-thick polyethylene naphthalate (PEN) film (trade name: teonex (product of Teijin dupont films)), to thereby obtain organic EL element 8.

On the day when the organic EL element 8 was formed, the organic EL element 8 exhibited almost the same performance as in the organic EL element of Example 3. On the following day, the light-emitting surface became smaller than that in the previous day. Although the light-extraction efficiency was not changed, the organic EL element did not emit light even upon current application 10 days after the formation. It is supposed that, since the water permeability of the substrate (PEN film) is higher than the value defined in claims (i.e., 0.1 g/m²/day), the organic layer (light-emitting layer) is damaged.

Note that the light-extracting substrate had a water permeability of 1 g/m²/day.

### <Evaluation>

### <<Brightness>>

Each of the above-obtained organic EL elements was measured in the dark for brightness with a luminance meter (SR-3, product of Top Com. Co.) such that light emitted from the surface of each light-emitting point was all received.

In this state, a constant current was applied to the organic EL element for lighting, and the brightness (cd/m²) thereof was measured. The thus-measured brightness was compared to that measured in an organic EL element having no light-extracting portion (lens), and the ratio was calculated. The results are shown in Table 1.

### <<Evaluation of Contrast>>

Each of the organic EL elements was measured for the brightness of the light-emitting pixel (one green pixel) and for the brightnesses of five consecutive pixels (not lit) adjacent to this light-emitting pixel. The brightnesses of the adjacent unlit pixels were compared to that of the light-emitting pixel, and the ratio was calculated (i.e., brightness of one light-emitting pixel: average brightness of five adjacent pixels). The results are shown in Table 1.

### <<Effective Amount of Light Emitted>>

The green light-emitting element of the organic EL element was driven for lighting so that a constant current was applied thereto. The spectrum of the light emitted (amount of light) was measured with a luminance meter (SR-3, product of Top Com. Co.). The spectrum of the light emitted (amount of light) and the current upon the measurement were used to calculate a light-emission efficiency (assuming that the distribution of the light emitted is Lambertian). The above-obtained light-emission efficiency (%), brightness of the unlit pixel and brightness of lit (light-emitting) pixel were used to calculate an effective amount of the light emitted using the following equation.

Effective amount of light emitted={light-emission efficiency (%)/(brightness of unlit pixel/brightness of lit pixel)}/100

TABLE 1

| | Bleeding | | | |
|---|---|---|---|---|
| | | | Brightness of light- | |
| | Brightness | Brightness | emitting pixel:average | Effective |
| | of lit | of unlit pixel | brightness of five | amount |
| | pixel | (five-point | unlit pixels (five- | of light |
| | (cd/m²) | average, cd/m²) | point average) | emitted |
| Ex. 1 | 1,000 | 1.5 | 667:1 | 267 |
| Ex. 2 | 950 | 1.3 | 731:1 | 278 |
| Ex. 3 | 975 | 1.4 | 696:1 | 271 |
| Ex. 4 | 725 | 1.1 | 659:1 | 191 |
| Comp. | 1,125 | 11.5 | 98:1 | 44 |
| Ex. 1 | | | | |
| Ex. 5 | 552 | 0.9 | 613:1 | 190 |
| Ex. 6 | 562 | 1.1 | 511:1 | 180 |
| Ex. 7 | 540 | 1.0 | 540:1 | 183 |
| Ex. 8 | 980 | 1.3 | 754:1 | 275 |

### INDUSTRIAL APPLICABILITY

The light-extraction member of the present invention can be suitably used in an organic EL element which is one light-emitting display device, and realizes high-definition, full-color display. Thus, the light-extraction member can be suitably used in a wide variety of applications including cell phone displays, personal digital assistants (PDAs), computer displays, vehicle's information displays, TV monitors and common lights.

What is claimed is:

1. A light-extraction member for use in a light-emitting display device, the light-extraction member comprising:
a light-extracting substrate which is disposed on the light-extraction side of the light-emitting display device,
a color filter layer formed over the light-extracting substrate, and
a lens member formed over the color filter layer,
wherein the color filter layer is bonded via an adhesive portion to a convex top portion of the lens member.

2. The light-extraction member according to claim 1, wherein a flat portion is present on the side of the lens member opposite to the light-extraction side thereof.

3. The light-extraction member according to claim 1, wherein a space is present between the lens member and the color filter layer in a light-extracting direction.

4. The light-extraction member according to claim 1, wherein the lens member has a refractive index of 1.4 to 2.1.

5. The light-extraction member according to claim 1, wherein the lens member is a hemispherical lens.

6. The light-extraction member according to claim 1, wherein the light-extracting substrate is made of a material having a water permeability of 0.1 g/m²/day or lower.

7. The light-extraction member according to claim 1, wherein the light-extracting substrate is a barrier film composed of a plurality of layers.

8. The light-extraction member according to claim 1, wherein the adhesive portion is the color filter layer.

9. The light-extraction member according to claim 1, wherein the adhesive portion is a layer formed through coating of the same material as the lens member.

10. An organic EL element comprising:
a light-extraction member for use in a light-emitting display device,
wherein the light-extraction member comprises a light-extracting substrate which is disposed on the light-extraction side of the light-emitting display device, a color filter layer formed over the light-extracting substrate, and a lens member formed over the color filter layer, and
wherein the color filter layer is bonded via an adhesive portion to a convex top portion of the lens member.

11. The organic EL element according to claim 10, wherein the color filter layer comprises a red filter portion, a green filter portion and a blue filter portion, which are located so that the red filter portion corresponds to an organic compound layer emitting red light, the green filter portion corresponds to an organic compound layer emitting green light, and the blue filter portion corresponds to an organic compound layer emitting blue light.

12. The organic EL element according to claim 10, wherein a flat portion is present at the lens member on the side opposite to the light-extraction side.

13. The organic EL element according to claim 10, wherein a space is present between the lens member and the color filter layer in a light-extracting direction.

14. The organic EL element according to claim 10, wherein the lens member has a refractive index of 1.4 to 2.1.

15. The organic EL element according to claim 10, wherein the light-extracting substrate is made of a material having a water permeability of 0.1 g/m²/day or lower.

16. The organic EL element according to claim 10, wherein the adhesive portion is the color filter layer.

17. A method for producing an organic EL element, the method comprising:
forming a light-extraction member which comprises a light-extracting substrate, a color filter layer and a lens member,
forming a light-emitting portion which comprises at least a substrate, a pair of electrodes on the substrate, and a light-emitting layer between the electrodes, and
joining together the light-extraction member and the light-emitting portion.

18. The method according to claim 17, wherein the forming the light-extraction member comprises forming the lens member on a temporary-bonding substrate, forming the color filter on the light-extracting substrate, bonding the color filter layer via an adhesive portion to a convex top portion of the lens member, and separating the temporary-bonding substrate from the lens member bonded to the color filter layer.
